(19) United States
(12) Patent Application Publication
(10) Pub. No.: US 2020/0373285 A1
(43) Pub. Date: Nov. 26, 2020

(54) POWER PASS-THROUGH DECOUPLING CAPACITANCE ARRANGEMENTS FOR INTEGRATED CIRCUIT DEVICES

(71) Applicant: Microsoft Technology Licensing, LLC, Redmond, WA (US)

(72) Inventors: William Paul Hovis, Sammamish, WA (US); Gregory M. Daly, Seattle, WA (US); Rich Tat An, Renton, WA (US)

(21) Appl. No.: 16/421,675

(22) Filed: May 24, 2019

(51) Int. Cl. H01L 25/16; H05K 1/18; H01L 23/13; H05K 1/02

(52) U.S. Cl. CPC H01L 25/16; H05K 1/181; H05K 1/183; H01L 23/13; H01L 24/16; H05K 2201/10015; H05K 2201/10378; H05K 2201/10734; H05K 1/0257

(57) ABSTRACT

Integrated circuit device carriers and packaging assemblies which have attached decoupling capacitance are discussed herein. In one example, an assembly includes a package assembly coupled to a motherboard and comprising a carrier circuit board and an integrated circuit device coupled to a first side of the carrier circuit board. The assembly also includes decoupling capacitors for the integrated circuit device conductively coupled between the motherboard and a second side of the carrier circuit board opposite from at least a portion of a footprint of the integrated circuit device on the carrier circuit board.

### BACKGROUND

Integrated circuit devices, such as central processor devices, graphics processors, or system-on-a-chip (SoC) devices can be employed in computing systems. These integrated circuit devices can have one or more voltage domains which correspond to particular power distribution subdivisions within the integrated circuit device. In large integrated circuit devices, operating frequency is a significant design concern, and many times an increased operating frequency is desired. However, a major barrier to increasing integrated circuit operating frequency is transient response and stability of the voltage domains supplying various processing units that form the integrated circuit device. These processing units, among other on-die components, can have power demands that vary rapidly and across a large power consumption range. As these power demands change over short time scales, voltage levels can experience dips or spikes, potentially leading to operational failures of the integrated circuit device.

Decoupling capacitors can be employed to reduce some transient effects related to these power demands Unfortunately, placement of decoupling capacitors on nearby printed circuit boards (PCBs) can lead to other sets of problems, and is limited in effectiveness because such placement is electrically far away from the integrated circuits. For example, inductance from interconnect and positioning between the decoupling capacitors and the target circuity limits the effectiveness of the decoupling capacitors. Moreover, these decoupling capacitors can take up valuable real estate on the package or motherboard circuit board and complicate circuit placement and routing.

### OVERVIEW

Integrated circuit device carriers and packaging assemblies which have attached decoupling capacitance are discussed herein. In one example, an assembly includes a package assembly coupled to a motherboard and comprising a carrier circuit board and an integrated circuit device coupled to a first side of the carrier circuit board. The assembly also includes decoupling capacitors for the integrated circuit device conductively coupled between the motherboard and a second side of the carrier circuit board opposite from at least a portion of a footprint of the integrated circuit device on the carrier circuit board.

In another example, an integrated circuit assembly includes a carrier circuit board coupled on a first side to an integrated circuit device, and having at least one cavity formed into a second side corresponding to at least a portion of a footprint of the integrated circuit device. The integrated circuit assembly includes decoupling capacitors for the integrated circuit device deposited into the at least one cavity and configured to conductively couple between a motherboard and the at least one cavity.

In another example, an apparatus includes a carrier circuit board coupled on a first side to an integrated circuit device. The apparatus includes decoupling capacitors for the integrated circuit device coupled to a second side of the carrier circuit board opposite from at least a portion of a footprint of the integrated circuit device, wherein at least a portion of the decoupling capacitors are configured to conductively couple between a motherboard and the carrier circuit board. The apparatus includes an interposer circuit board coupled to the second side of the carrier circuit board and configured to accommodate a thickness of the decoupling capacitors between the carrier circuit board and a motherboard when mated to the interposer circuit board.

This Overview is provided to introduce a selection of concepts in a simplified form that are further described below in the Detailed Description. It may be understood that this Overview is not intended to identify key features or essential features of the claimed subject matter, nor is it intended to be used to limit the scope of the claimed subject matter.

### BRIEF DESCRIPTION OF THE DRAWINGS

Many aspects of the disclosure can be better understood with reference to the following drawings. While several implementations are described in connection with these drawings, the disclosure is not limited to the implementations disclosed herein. On the contrary, the intent is to cover all alternatives, modifications, and equivalents.

FIG. 1 illustrates an integrated circuit assembly having an interposer with an aperture in an implementation.

FIG. 2 illustrates views of an integrated circuit assembly having an interposer with an aperture in an implementation.

FIG. 3 illustrates a side view of an integrated circuit assembly having an interposer with a hidden cavity in an implementation.

FIG. 4 illustrates an integrated circuit assembly having an interposer with an aperture in an implementation.

FIG. 5 illustrates a side view of an integrated circuit assembly having an interposer with an aperture and pass-through decoupling capacitors in an implementation.

FIG. 6 illustrates an integrated circuit assembly having a motherboard with a cavity in an implementation.

FIG. 7 illustrates a side view of an integrated circuit assembly having a motherboard with a cavity in an implementation.

FIG. 8 illustrates a side view of an integrated circuit assembly having a motherboard with a cavity and pass-through decoupling capacitors in an implementation.

FIG. 9 illustrates a side view of an integrated circuit assembly having a motherboard with multiple cavities in an implementation.

FIG. 10 illustrates a side view of an integrated circuit assembly having a motherboard with multiple cavities and pass-through decoupling capacitors in an implementation.

FIG. 11 illustrates a side view of an integrated circuit assembly having a carrier with a cavity in an implementation.

FIG. 12 illustrates a side view of an integrated circuit assembly having a carrier with a cavity and pass-through decoupling capacitors in an implementation.

FIG. 13 illustrates a side view of an integrated circuit assembly having a carrier with multiple cavities in an implementation.

FIG. 14 illustrates a side view of an integrated circuit assembly having a carrier with multiple cavities and pass-through decoupling capacitors in an implementation.

### DETAILED DESCRIPTION

In integrated circuit devices, such as system-on-a-chip (SoC) and processor designs, operating frequency can be a significant driver of performance. A major roadblock to increasing processor frequency is the transient response and stability of the voltage rails supplying execution units of the processor. Thus, an effective strategy is desired to decrease the influence of high frequency voltage transient events, such as dips or droops, among other transient events. A simple tool to evaluate the effectiveness of a decoupling capacitor can be measuring a path that electrical current takes when traveling to a capacitor and back. The area inside this path or loop translates to inductance, and this inductance limits the frequencies over which the capacitor can be effective for decoupling purposes.

As mentioned above, decoupling capacitors can be positioned on a main circuit board outside of a perimeter of an SoC. However, this positioning can still leave relatively long distances between the decoupling capacitors and the target circuity, which can have associated inductance and further exasperate the negative influences of transient events. Main board perimeter decoupling capacitors are typically too far away from an affected circuit and have too much inductance to relieve very fast transients on SoC devices. Some decoupling capacitors are placed in a land-side configuration on a die carrier, referred to as land-side capacitors (LSCs). These land-side capacitors are placed on a circuit board package on the opposite side of the silicon die. In recent SoC and processor designs, these land-side capacitors have fallen out of popularity, as using them prevents a package designer from placing solder pads/balls for the die in the area directly underneath the die, and makes routing circuit board traces more complex. Vertical clearance between the die carrier and the PCB that its mounted on would also be required to accommodate these capacitors, which is not always possible. This increases a size of the die carrier (costing more) and also compromises power delivery of a main board voltage regulator system. Thus, die-side carrier perimeter decoupling capacitors have been employed instead, referred to as die-side capacitors (DSCs). These are decoupling capacitors placed on a top side of the die carrier, outside of a perimeter adjacent to the semiconductor die. An examination of the associated current loops indicate that these DSCs are less effective than LSCs because the associated capacitor distance is much greater from the die. For this reason, DSCs struggle to contribute effectively to voltage droop mitigation during very fast transient events.

Another solution is to integrate capacitance into the same die as the integrated device itself. Since capacitance is directly related to unit area, any addition of capacitive structures on the die results in more die area. Thus, this technique is typically an expensive venture leading to larger dies and increasing costs. Also, on-die decoupling capacitors take up valuable circuit real estate, complicate fabrication, and can unintentionally space apart processing units or other functional elements leading to logic routing and placement complications. High-performance processors are often built using the latest fabrication technology and smallest feature sizes, and thus are the most expensive to manufacture, so any increase in die area for capacitance also increases the total integrated circuit cost dramatically. Adding capacitance structures to make the die larger also can create challenges for semiconductor designers, since capacitance structures can displace functional logic or processing cores, and affected signals must travel farther. This can lead to difficultly in placement and routing, as well as establishing proper timing relationships among logic/cores.

In the examples herein, several example implementations of enhanced decoupling capacitance arrangements and arrangements are discussed. These capacitance arrangements comprise a plurality of capacitors placed underneath an integrated circuit device which is coupled to a carrier or package. For example, a chip-scale integrated circuit device, such as a flip-chip device, might be coupled to a first side of a carrier circuit board to provide for pinout and power to the integrated circuit device. A second side of the carrier typically has a pinout or ball grid arrangement for coupling the carrier to a motherboard or other similar circuit assembly. Together, the integrated circuit device and carrier circuit board can form a package assembly. Decoupling capacitors can be added to the package assembly on an opposite side of the carrier circuit card than that of the integrated circuit device, which can be referred to as the land-side capacitance (LSC) configuration. In some examples, various apertures or cavities are included in the carrier circuit board or a mating motherboard to accommodate a vertical thickness or stackup of the decoupling capacitors when the package assembly is mounted to a motherboard. In other examples, an interposer circuit card is provided between the carrier circuit board and the motherboard to provide for apertures or cavities which accommodate the decoupling capacitors when the package assembly is mounted to a motherboard. In yet further examples, the decoupling capacitors can be employed to transfer power between a motherboard and the carrier circuit card by coupling terminals of the decoupling capacitors between the motherboard and the carrier circuit card or interposer circuit card.

Advantageously, the arrangements and assemblies presented herein provide for several alternative implementations of adding decoupling capacitors for integrated circuit devices. These decoupling capacitors are placed very near to portions of the integrated circuit device which consume power and may experience transient operation or dynamic power consumption. In this manner, voltage dips and droops can be greatly reduced for the integrated circuit device without adding unwanted inductance from decoupling capacitors which might be placed outside a perimeter of the integrated circuit device or outside perimeters of associated packaging or carrier assemblies.

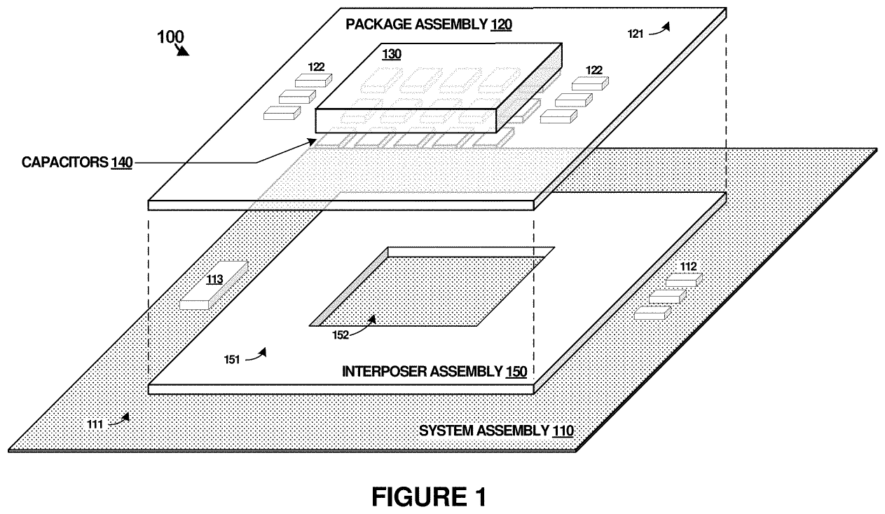

Turning now to a first example implementation, FIG. 1 is presented. FIG. 1 illustrates an integrated circuit arrangement 100 in an implementation. In FIG. 1, system circuit board 111 of system assembly 110 is conductively coupled to package assembly 120. Package assembly comprises carrier circuit board 121 for integrated circuit device 130. A plurality of decoupling capacitors 140 are placed “underneath” a shadow or footprint of at least a portion of integrated circuit device 130. The terms underneath or below refer to a side of carrier circuit board 121 opposite the side onto which integrated circuit device 130 is mounted or coupled. This opposite side can be referred to as land-side in some examples.

Interposer assembly 150 is also included in FIG. 1 and comprises interposer circuit board 151 and aperture 152. Aperture 152 can accommodate capacitors 140 when a further assembly comprising package assembly 120 and interposer assembly 150 is mounted to system circuit board 111. In this manner, interposer circuit board 151 forms a quasi-donut shape which at least partially surrounds capacitors 140 and provides vertical offset for capacitors between carrier circuit board 121 and system circuit board 111. Interposer assembly 150 also conductively couples signals and power between system circuit board 111 and carrier circuit board 121.

In typical configurations, integrated circuit device 130 comprises various processing cores, interfacing logic, power distribution structures, and the like. Integrated circuit device 130 is bonded or otherwise coupled to carrier circuit board 121 of package assembly 120. Together, package assembly with integrated circuit device 130 might comprise a system-on-a-chip (SoC), central processing unit (CPU), or graphics processing unit (GPU), among other integrated devices. This integrated device can be coupled to a system board, such as a motherboard, comprising system circuit board 111 for integration into a computing system. Various support circuitry, such as memory, storage, peripherals, power supplies, and other related circuitry, can be included on such a system board, also referred to as a motherboard. This other related and support circuitry is omitted for simplicity. System assembly 110 can comprise this system board, as well as other components.

In operation, dynamic power demands and electromagnetic interference concerns might warrant one or more decoupling capacitors. Various decoupling capacitors can be placed onto system assembly 110 and package assembly 120, such as around perimeters of integrated circuit device 130 and package assembly 120. In FIG. 1, a first set of decoupling capacitors 112 are positioned onto system circuit board 111. A second set of decoupling capacitors 122 are positioned onto package assembly 120. Decoupling capacitors 112 and 122 can reduce voltage fluctuations due to transient effects of integrated circuit device 130, as well as reduce susceptibility and emissions with regard to electromagnetic interference. However, due to the distances between decoupling capacitors 112 and 122 and relevant portions of integrated circuit device 130, relatively large current loops can be formed, leading to increased inductance on the affected voltage links of included power domains. These inductances, among other factors, can limit the transient speeds or maximum frequencies over which decoupling features are effective. When these decoupling features are not sufficient to reduce transients on voltage links, such as droops, dips, and spikes, among other transient events, then operation of integrated circuit device 130 can be reduced. Failures can even result during larger transient events and dynamic changes in power demands of integrated circuit device 130.

One potential way to compensate for voltage dips and droops is to increase a level of a voltage supplied the various power domains of integrated circuit device 130. For example, if a particular voltage domain specifies 1.00 VDC, then an increase to 1.05 VDC or 1.10 VDC might aid tolerance of integrated circuit device 130 to various voltage dips. However, this not only can waste energy, but lead to higher power dissipation within integrated circuit device 130, and thus increased heating. In FIG. 1, instead of increasing a supply voltage level, or altering a quantity or arrangement of capacitors around a perimeter of integrated circuit device 130 or package assembly 120, an enhanced arrangement is shown.

Specifically, FIG. 1 shows capacitors 140 which are positioned onto an opposite side of carrier circuit board 121 than integrated circuit device 130, referred to as the land-side in some examples. Capacitors 140 are placed underneath a shadow or footprint of integrated circuit device 130, providing for a very close physical location between capacitors 140 and associated portions of integrated circuit device 130. The loop inductance between capacitors 140 and the circuits on integrated circuit device 130 is proportional to the vertical distance through package assembly 120. Capacitors 140 can be individually connected to power distribution features of integrated circuit device 130. Capacitors 140 can be conductively connected to integrated circuit device 130 using one or more circuit board vias incorporated into carrier circuit board 121. In this manner, capacitors 140 can be positioned very near power features of integrated circuit device 130 to significantly decrease any distance between capacitance structures and affected power features. Inductive loop distance/area can also be correspondingly reduced between capacitors 140 and power features of integrated circuit device 130, leading to faster transient response for voltage domains. Thus, an actual supplied voltage level experiences much smaller deviations from a desired voltage level or circuit minimum voltage levels. Such assemblies formed with capacitors 140 and integrated circuit device 130 can improve a minimum voltage (Vmin) needed to supply a particular integrated circuit by 50-100 mV or more which translates into a 10-20% improvements in device power efficiency. If desired, these efficiency gains in Vmin operation can be translated into supplying a lower voltage level to the affected circuit, which can reduce power dissipation and increase performance for a particular operating frequency.

FIG. 1 illustrates discrete capacitors 140 as a part of an enhanced surface mount capacitor arrangement. Capacitors 140 can be coupled mechanically and electrically to carrier circuit card 121 using external features included on both capacitors 140 and carrier circuit card 121, such as terminals and conductive pads coupled using solder. Capacitors 140 can be bonded using reflow soldering or similar techniques to conductively couple individual capacitors to conductive pads of carrier circuit board 121. Integrated circuit device 130 can be in a flip-chip configuration for bonding of a top-side of integrated circuit device 130 to carrier circuit board 121, and with a bottom-side of integrated circuit device 130 coupled to casing elements, heat spreader elements, or heat sink elements. A side of carrier circuit board 121 opposite that of integrated circuit device 130 can comprise conductive pads to couple to capacitors 140. In this matter, a more direct connection through associated conductive pads and circuit board vias or traces can be established between integrated circuit device 130 and capacitors 140. It should be understood that the flip-chip configuration need not be employed to couple integrated circuit device 130, and top-side/bottom-side terminology is merely exemplary.

In other examples, an integrated capacitance device might be employed instead of discrete capacitors. An integrated capacitance device can comprise a plurality of individual capacitors formed by semiconductor-based capacitance structures. This integrated capacitance device can comprise a semiconductor wafer-fabricated integrated circuit. An integrated capacitance device can include a semiconductor capacitor array comprising an integrated array of silicon-based, metal-oxide-semiconductor, or metal-insulator-semiconductor capacitance elements. Other semiconductor structures can be included, such as transistors, interconnect, and various active and passive circuitry. Various interconnect might be included in an integrated capacitance device to form zones, groups, or other customized configurations among capacitance structures. Additionally, interconnect is employed to couple terminals of various capacitance structures and grouped capacitance structures to external interconnection features, such as conductive pads or external interfacing elements. An integrated capacitance device can be a thinned device where a back or bottom substrate portion is shaved or etched thinner to reduce a thickness for enhanced thermal dissipation or reduction in stackup height.

Turning now to a detailed discussion on the elements of FIG. 1, system assembly 110 comprises one or more printed circuit boards (PCBs) or circuit card assemblies (CCAs) formed using various circuit board manufacturing processes. System assembly 110 can comprise a computing system motherboard or daughterboard in many examples. System assembly 110 can include circuit boards as well as components mounted to the circuit boards. In FIG. 1, system assembly 110 includes exemplary system circuit board 111, although other configurations are possible. System circuit board 111 can comprise fiber-infused dielectric materials, such as fiberglass, FR4, or various composite materials. System circuit board 111 comprises two surfaces or sides as well as several layers of alternating insulating board material and conductive interconnect or traces formed with metal etchings or printed conductive features. System circuit board 111 can include one or more power distribution layers/planes or grounding layers/planes which form one or more layers of the associated circuit board. System circuit board 111 can include conductive vias which can penetrate an entire layered stackup of system circuit board 111 or a subset of layers, which may or may not include hidden or buried vias. System circuit board 111 can include labeling/screen printing, solder mask material, and chassis mounting features.

Decoupling capacitors 112 can be included on system circuit board 111 within system assembly 110. Capacitors 112 can comprise surface mount, multilayer ceramic capacitors (MLCCs), through-hole, or other types of discrete capacitors. Similarly, capacitors 122 can comprise similar types of capacitors as capacitors 112. Capacitors 112 and 122 can be of various sizes, such as 0201, 0402, or 0603 size surface mount capacitors, among others.

Power supply circuitry 113 comprises various power conditioning, filtering, and handling components which accept input power for a system comprising elements in FIG. 1. In one example, power supply circuitry 113 comprises a plurality of power phases each comprising voltage conversion circuitry to step down or step up source power to various supply voltages or input voltages provided to integrated circuit device 130, among other components on system assembly 110. These power phases can each have an associated controlled voltage level, which might be variable or adjustable depending upon conditions, performance testing, minimum necessary voltages, or other factors. The power phases can provide power to integrated circuit device 130 over dedicated circuit links comprising circuit traces, circuit board vias, and power planes which route the power from circuitry represented by power supply circuitry 113 over system circuit board 111 and other elements including interposer assembly 150 and package assembly 120. Individual decoupling capacitors or groups of decoupling capacitors can be connected to these dedicated circuit links, as shown in FIG. 1 for capacitors 140.

Package assembly 120 comprises an integrated circuit package which includes a carrier comprising a printed circuit board, typically smaller than that of system assembly 110. Package assembly 120 can comprise similar materials as system assembly 110, such as layers of insulating and conductive materials with associated traces, planes, routing, vias, and the like. Package assembly 120 couples to system assembly 110 via one or more solder bumps or solder features, such as controlled collapse chip connection (C4) balls. Typically pins and sockets are not employed for package assembly 120, but in some examples are possible. Package assembly 120 can comprise a flip-chip assembly when fitted with an associated die of an integrated circuit, such as integrated circuit device 130. Package assembly 120 has a first surface or side (referred to as a die side) which couples to integrated circuit device 130 and a second surface or side (referred to as a land side) which couples to a system assembly PCB via solder features, such as conductive pads and solder balls.

Integrated circuit device 130 comprises a microprocessor, central processing unit (CPU), graphics processing unit (GPU), system-on-a-chip (SoC), application-specific integrated circuit (ASIC), field-programmable gate array (FPGA) tensor processing unit (TPU), or baseband processing unit (BBU), among other analog and digital integrated circuits. Integrated circuit device 130 is formed using various semiconductor manufacturing processes, such as employed in semiconductor wafer fabrication. Integrated circuit device 130 can comprise silicon-based circuit, but might also include other types of semiconductor materials as well as associated conductive interconnect. Integrated circuit device 130 includes various layers, logic devices, interconnect, metallization, processing cores, and interfacing circuitry. Integrated circuit device 130 comprises one or more power domains, each having a characteristic voltage level. Integrated circuit device 130 can comprise a flip-chip design which has external pads on a top side of chip (with regard to a manufacturing directionality), and is coupled to carrier circuit board 121 of package assembly 120 via solder features/balls, controlled collapse chip connection (C4) balls or other conductive bonding processes.

Capacitors 140 can comprise surface mount, multilayer ceramic capacitors (MLCCs), or other types of discrete capacitors or various materials, including semiconductor capacitors. Capacitors 140 can be of various sizes, such as 0201 or 0204 sizes, or of larger sizes such as 0603 or 0402 size surface mount capacitors, among others. In an alternative example, instead of discrete or individual capacitors, capacitors 140 might comprise an integrated capacitance element having an array of individual capacitors integrated into a silicon or semiconductor die. This semiconductor capacitor array might comprise an integrated array of metal-oxide-semiconductor or metal-insulator-semiconductor capacitance elements which have associated zones or groups to couple individual capacitance elements into larger sets for coupling to external circuitry. Conductive pads and associated metallized interconnect can be integrated into the semiconductor capacitor array for coupling the capacitance elements to external circuitry, such as via C4 balls to conductive pads of carrier circuit board 121.

Interposer 150 comprises circuit board 151 and aperture 152. Interposer 150 can comprise similar materials as system assembly 110, such as layers of insulating and conductive materials with associated traces, planes, routing, vias, and the like. Interposer 150 couples to both system circuit board 111 and carrier circuit board 121 via one or more solder bumps or solder features, such as C4 balls and associated conductive pads. Typically, pins and sockets are not employed for interposer 150, but in some examples are possible. Interposer 150 might be included in package assembly 120, and pre-assembled before coupling to system assembly 110. Interposer 150 can couple communication signals and power between system circuit board 111 and carrier circuit board 121 through associated pass-through connections comprising vias, circuit traces, power planes, and the like. In some examples, the ball arrangement on interposer 150 matches that provided by carrier circuit card 121, and thus can couple to system circuit board 111 in a similar connection arrangement or pinout/ballout to that of package assembly 120.

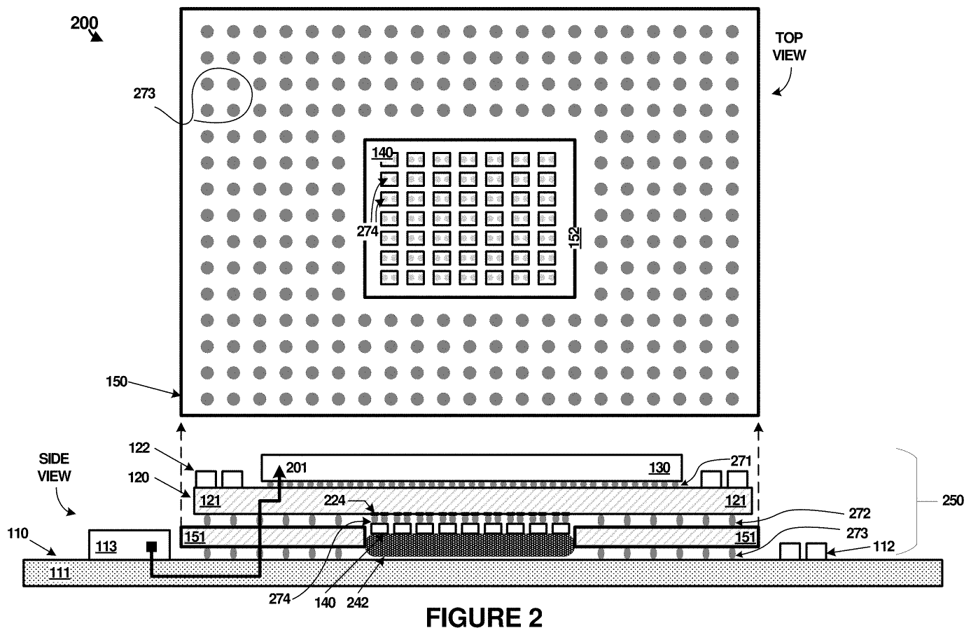

FIG. 2 illustrates top and side views of an integrated circuit assembly comprising interposer assembly 150 with aperture 152 in an implementation. Although similar elements as found in FIG. 1 are shown in FIG. 2, it should be understood that other elements can instead be included. Also, many elements in FIG. 2 are not drawn to scale, and instead are sized to enhance clarity in the associated discussion.

FIG. 2 includes a top view of integrated circuit device 130 to illustrate associated interconnect with respect to capacitors 140. In FIG. 2, the top view of interposer assembly 150 is shown having interposer circuit board 151 overlaid with conductive pads of carrier circuit board 121 (grey dots). The grey dots in FIG. 2 represent solder balls 274 and conductive pads 224 of carrier circuit board 121 which are connected to power features of integrated circuit device 130, such as voltage domains, voltage/ground planes, or voltage/ground links, as indicated by corresponding boxes. Traces, planes, or links of carrier circuit board 121 conductively couple conductive pads 224 to corresponding solder balls 271 and conductive pads of integrated circuit device 130. Aperture 152 can be seen in this top view, along with a grid arrangement of solder balls 273 of interposer assembly 150.

FIG. 2 includes side view 200 to illustrate a stackup among system assembly 110, package assembly 120, integrated circuit device 130, interposer assembly 150, and capacitors 140. At a bottom of the stackup in FIG. 2, system assembly 110 is shown having one or more perimeter decoupling capacitors 112 and power supply circuitry 113. Further circuity can be included in system assembly 110, such as memory, storage, peripherals, power distribution circuity, and other similar elements. These are not shown in FIG. 2 for clarity. Integrated circuit device 130 comprises a semiconductor die which is bonded to carrier circuit board 121 of package assembly 120. This configuration might comprise a flip-chip configuration, although other configurations are possible. Solder balls 271 couple integrated circuit device 130 to carrier circuit board 121 to form package assembly 120, along with other circuitry which might include perimeter decoupling capacitors 122. Package assembly 120 is also coupled using solder balls 272 to interposer assembly 150. Interposer assembly 150 is coupled via solder balls 273 to system assembly 110.

Package assembly 120 can include interposer assembly 150 which has interposer circuit board 151 coupled to carrier circuit board 121. Chip-scale assembly 250 is shown in FIG. 2 as comprising integrated circuit 130, carrier circuit board 121, and interposer circuit board 151, along with associated solder balls 271, 272, and 273. Furthermore, capacitors 140 are coupled to a bottom size of carrier circuit board 121 via solder balls 274 and conductive pads 224. Various potting 242, such as epoxy, filler, thermal compound, or other material can be deposited into aperture 152 of interposer circuit board 151. This potting 242 can be added prior to mating of chip-scale assembly 250 to system circuit board 111. Potting 242 can aid in mechanical holding and stability of capacitors 140 once capacitors 140 are bonded or soldered to the bottom size of carrier circuit board 121. Gaps between capacitors 140 can accept portions of potting 242 for further mechanical stability. Potting 242 can also aid solder reflow operations when mating chip-scale assembly 250 to system circuit board 111 via solder balls 273, such as to prevent movement or de-soldering of capacitors 140 from conductive pads 224 or solder balls 274.

Placement of capacitors 140 on carrier circuit board 121 can correspond to various areas of integrated circuit device 130 that can benefit from decoupling capacitance, due in part to having dynamic operation with high power demand and susceptibility to voltage transients. Example areas of integrated circuit device 130 include processing cores, graphics cores, input/output cores, memory bus cores, and other similar elements. Some areas of the device may be somewhat immune from such concerns, due to either low power demands overall or having consistent power demand that varies little and thus corresponds to low power supply noise.

Advantageously, the stackup formed by chip-scale assembly 250 provides for decoupling capacitance of capacitors 140 near to affected circuity of integrated circuit 130. Decoupling capacitors 140 thus become more effective at reducing high-frequency transients in power lines and power domains of integrated circuit device 130. Moreover, since correspondingly short links are needed between capacitors 140 and integrated circuit device 130, such as compared to capacitors 112 and 122, inductance between capacitors 140 and integrated circuit device 130 is also minimized Interposer circuit board 151 provides for standoff of carrier circuit board 121 from system circuit board 111 to allow for a vertical height or vertical stackup of capacitors 140. Although FIG. 2 shows one example stackup height or vertical height of capacitors 140 and of chip-scale assembly 250, interposer circuit board 151 can be configured to accommodate varying heights of capacitors 140, such as by varying a thickness of circuit board layers or quantity of circuit board layers included in interposer circuit board 151. Aperture 152 provides for clearance through interposer circuit board 151 for capacitors 140. Although a single aperture 152 is included, other examples might have more than one aperture, and each aperture might accommodate one or more of capacitors 140.

A final assembly having elements 110, chip-scale assembly 250, and any applicable heat sinks would provide substantially improved placement of power supply decoupling capacitors 140 for integrated circuit device 130 that allows for improved performance and/or reduced power supply voltages due to decreased power supply noise. This can also lead to improved circuit operating voltage minimum (Vmin) values by having less dynamic variation in voltage levels provided to the individual power domains. The closely-positioned decoupling capacitance can lead to better dynamic performance on any associated voltage lines and voltage domains of integrated circuit device 130, allowing for lower operating voltages for the domains of integrated circuit device 130, and hence lower power. Voltage optimization techniques might be controlled by power supply circuitry 113 to reduce supply voltages to integrated circuit device 130. These voltage optimization techniques can also benefit from the closely-positioned decoupling capacitances shown herein. Specifically, a reduced magnitude of transient effects on voltage domains from the close decoupling capacitance can also correspond to reduced voltage levels needed to be supplied to a given circuit.

In addition to capacitors 140, other circuitry can be placed into aperture 152 formed by interposer circuit board 151. This other circuitry can include passive and active electrical components, power supply circuitry, voltage lowering circuity for integrated circuit device 130, various integrated circuitry, resistors, inductors, transistors, and other similar circuitry.

To illustrate power flow through a final assembly having chip-scale assembly 250 mated to system assembly 110, example power flow 201 is shown. Power flow 201 can be for any exemplary power link, voltage domain, ground, or reference voltage provided to integrated circuit device 130. Input power/voltage is received from an external power source, conditioned and converted by power supply circuitry 113 and provided to circuit board traces/planes of system circuit board 111. For example, V_{DD} and ground for integrated circuit device 130 can be represented by power flow 201 and routed through one or more solder balls in FIG. 2. Power flow 201 can be replicated for more than one instance of V_{DD} and ground for individual power domains of integrated circuit device 130. One or more conductive paths formed by solder balls 273 and associated conductive pads route power flow 201 through conductive elements of interposer circuit board 151 and carrier circuit board 121 to reach integrated circuit device 130. In this example, power flow 201 does not pass through terminals of capacitors 140, although other power may flow through terminals of capacitors which is related to decoupling operations. Instead, capacitors tap into power traces, planes, or vias of carrier circuit board 121. In many of the examples herein, however, power flow is provided though terminals of decoupling capacitors.

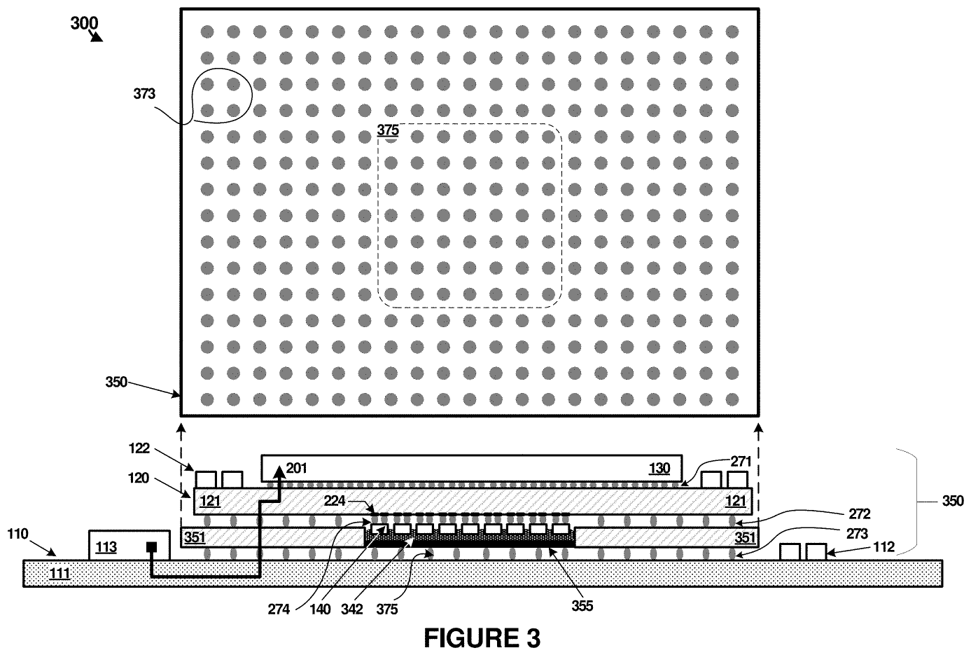

FIG. 3 illustrates top and side views of integrated circuit assembly 300 comprising interposer assembly 350. Although similar elements as found in FIGS. 1 and 2 are shown in FIG. 3, it should be understood that different elements can instead be included. Also, many elements in FIG. 3 are not drawn to scale, and instead are sized to enhance clarity in the associated discussion. FIG. 3 illustrates an alternative interposer arrangement than that seen in FIG. 2.

Specifically, no aperture 152 in interposer circuit board 150 is seen in FIG. 3, and instead a cavity 355 is formed into interposer circuit board 351. Cavity 355 comprises a partial reduction in a thickness of interposer circuit board 351, such as by milling, etching, drilling, or routing out one or more circuit board layers. Cavity 355 can still contain one or more substrate layers, which may comprise routable conductive layers and insulating layers. A depth of cavity 355 can correspond to a vertical height or stackup of capacitors 140 when mated to carrier circuit board 121, or can be of other depths to accommodate other elements. Together, assembly 350 comprising interposer circuit board 351, package assembly 120, and integrated circuit device 130 can form a discrete assembly which can be mounted to system circuit board 111. Assembly 350 accommodates decoupling capacitors 140 in a protected pocket formed by cavity 355 and carrier circuit board 121, which can be filled with potting material 342 to provide for enhanced mechanical stability, thermal performance, and tamper resistance. Furthermore, additional electrical connections can be provided via solder balls 375 and associated conductive pads below cavity 355. These additional electrical connections which are under cavity 355 can carry communication signaling or power for integrated circuit device 130 or for additional circuity included. Solder balls 375 and 273 might both be included for attachment of assembly 350 to system circuit board 111, but solder balls 375 may be omitted in some examples.

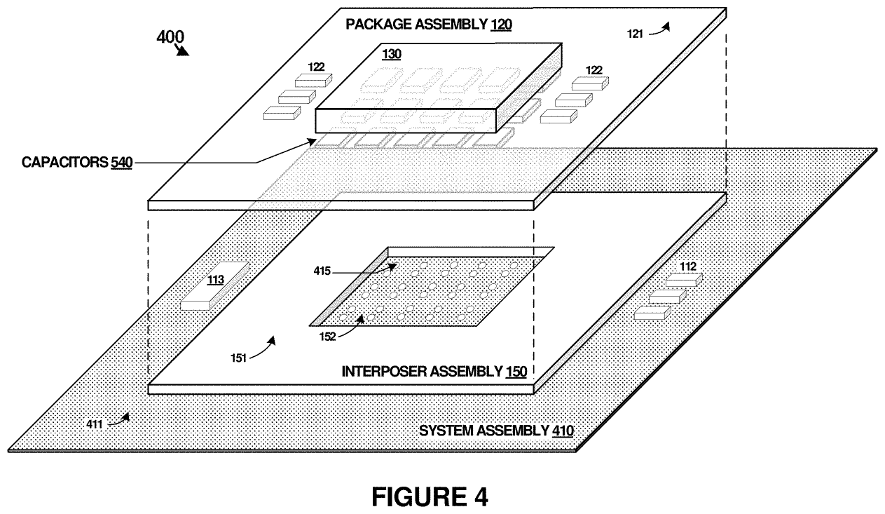

FIG. 4 illustrates integrated circuit assembly 400 having interposer assembly 150 with aperture 152 in an implementation. FIG. 4 illustrates an alternative decoupling capacitor arrangement than that seen in FIGS. 1-3. Although similar elements as found in FIGS. 1-3 are shown in FIG. 4, it should be understood that different elements can instead be included. In FIG. 4, an arrangement is provided which routes at least a portion of the power and grounding for integrated circuit device 130 through terminals of decoupling capacitors 540. Conductive pads 415 are provided on system circuit board 411 of system assembly 410 which couple to traces, planes, or vias which carry one or more voltages and reference potentials for integrated circuit device 130. These one or more voltages and reference potentials can be supplied by power supply circuitry 113.

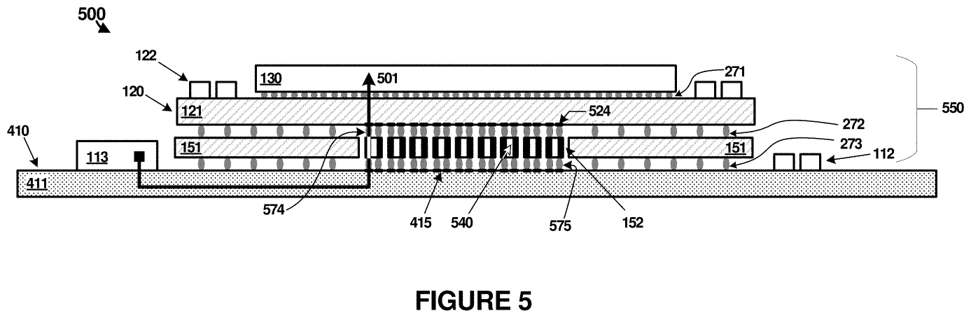

To further illustrate the enhanced features of elements in FIG. 4, a side view is presented in FIG. 5. FIG. 5 illustrates side view 500 of an integrated circuit assembly having interposer 150 with aperture 152 and decoupling capacitors 540 providing power pass-through in an implementation. These power pass-through features comprise coupling at least a portion of the power supplied to integrated circuit device 130 through terminals of capacitors 540. Advantageously, a more direct route of power and ground connections is provided to integrated circuit device 130, with decoupling capacitance very near to power input terminals of integrated circuit device 130. Moreover, the conductive nature of the power pass-through features can aid in thermal conduction via metal elements for integrated circuit device 130. Tighter tolerances on a stackup or height between carrier circuit board 121, interposer circuit board 151, and system circuit board 411 might be needed, along with more accurate control over placement and positioning of capacitors 540. Capacitors 540 also are coupled to conductive pads of two circuit boards, namely conductive pads 524 of carrier circuit board 121 and conductive pads 415 of system circuit board 411. However, the performance advantages of such an arrangement can outweigh any increased manufacturing complexity.

To aid mating of capacitors 540 to both system circuit board 411 and carrier circuit board 121, a pre-assembled chip-scale assembly 550 can be produced. This chip-scale assembly 550 comprises integrated circuit device 130 coupled to carrier circuit board 121, and carrier circuit board 121 coupled to interposer circuit board 151. Capacitors 540 can then be coupled to carrier circuit board 121 using solder reflow processes to couple capacitors 540 to conductive pads on the ‘underside’ or ‘landside’ of carrier circuit board 121. Then, chip-scale assembly 550 can be mated to system circuit board 411. Various potting or epoxy filler might be placed into aperture 152 to mechanically secure capacitors 540 after soldering is completed. Thus, when a secondary solder reflow process occurs to mate chip-scale assembly 550 to system circuit board 411, capacitors 540 can remain secure in the soldered locations without danger of movement or inadvertent de-soldering. Other techniques can be employed, such as using solder materials with different melting points for different sets of solder balls.

System circuit board 411 can comprise similar elements and configurations as system circuit board 111. However, system circuit board 411 includes conductive pads 415. System assembly 410 also can comprise similar elements as system assembly 110, such as power supply circuity 113 and decoupling capacitors 112, among other elements.

Capacitors 540 can comprise similar elements as described herein for capacitors 140. However, variations in capacitors 540 can be established to account for soldering terminals to two different circuit boards. Moreover, a thickness or stackup height of capacitors 540 might vary to match a desired stackup within aperture 152 or formed by carrier circuit board 121, interposer circuit board 151, and system circuit board 111. Conductive spacers for terminals of capacitors 540 other similar features might be employed when capacitors are too thin vertically to fit properly in the vertical stackup. When an integrated capacitance device is employed, such as a semiconductor die with individual capacitance elements formed thereon, then this capacitance device might have conductive pads on both surfaces of the die, along with any associated internal power and ground coupling features, such as routes, planes, through-silicon vias. A thickness of the integrated capacitance device might be sized according to a vertical stackup within aperture 152 or formed by carrier circuit board 121, interposer circuit board 151, and system circuit board 111.

In addition to capacitors 540, other circuitry can be placed into aperture 152 formed by interposer circuit board 151. This other circuitry can include passive and active electrical components, power supply circuitry, voltage lowering circuity for integrated circuit device 130, various integrated circuitry, resistors, inductors, transistors, and other similar circuitry.

To illustrate power flow through a final assembly having chip-scale assembly 550 mated to system assembly 410, example power flow 501 is shown. Power flow 501 can be for any exemplary power link, voltage domain, ground, or reference voltage provided to integrated circuit device 130. Input power/voltage is received from an external power source, conditioned and converted by power supply circuitry 113 and provided to circuit board traces/planes of system circuit board 411. For example, V_{DD} and ground for integrated circuit device 130 can be represented by power flow 501 and routed through one or more terminals of capacitors 540. Power flow 501 can be replicated for more than one instance of V_{DD} and ground for individual power domains of integrated circuit device 130. One or more conductive paths formed by conductive pads 415, solder balls 575, terminals of selected capacitors 540, solder balls 574, and conductive pads 524 route power flow 501 through conductive elements of interposer circuit board 151 and carrier circuit board 121 to reach integrated circuit device 130. In this example, power flow 501 passes through terminals of capacitors 540. A portion of the power flow may also be routed through solder balls 272 and 273 as seen in power flow 201 in FIG. 2.

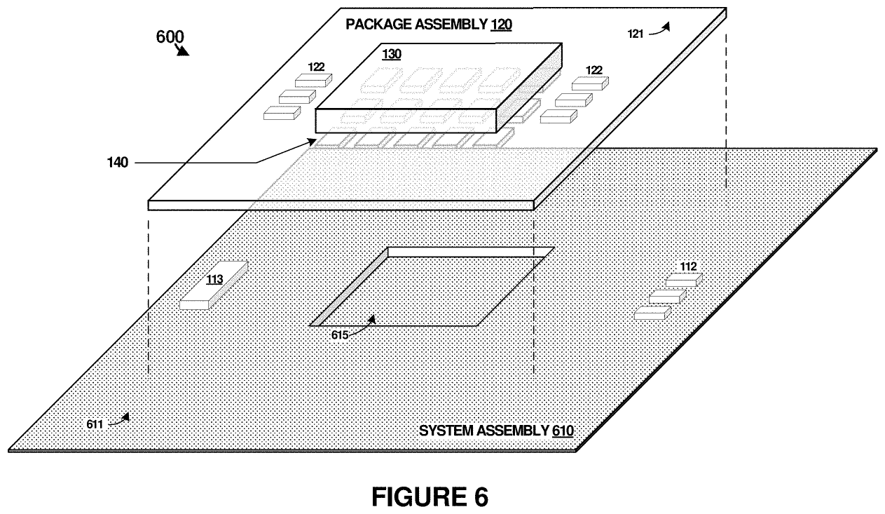

FIG. 6 illustrates integrated circuit assembly 600 having system assembly 610 comprising motherboard 611 with cavity 615 in an implementation. FIG. 6 illustrates an alternative decoupling capacitor arrangement than that seen in FIGS. 1-5. Although similar elements as found in FIGS. 1-5 are shown in FIG. 6, it should be understood that different elements can instead be included. In FIG. 6, an arrangement is provided with cavity 615 to allow for a vertical stackup of decoupling capacitors 140 below a shadow or footprint of integrated circuit device 130 on package assembly 120. The terms underneath or below refer to a side of carrier circuit board 121 opposite the side onto which integrated circuit device 130 is mounted or coupled, which can be referred to as the land-side. In contrast with FIGS. 1-5, integrated circuit assembly 600 in FIG. 6 lacks an interposer circuit board or associated interposer assembly.

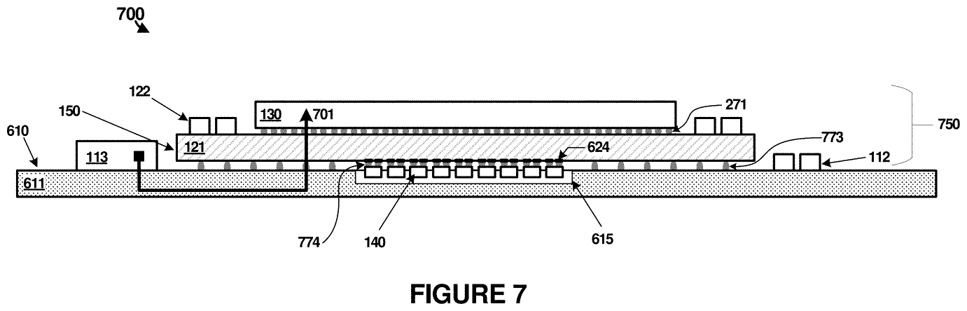

To further illustrate the enhanced features of elements in FIG. 6, a side view is presented in FIG. 7. FIG. 7 illustrates side view 700 of an integrated circuit assembly having cavity 615 formed into motherboard 611 to accommodate decoupling capacitors 140. Capacitors 140 are coupled to conductive pads 624 of carrier circuit board 121. Motherboard 611 can comprise similar elements and configurations as system circuit board 111. However, motherboard 611 includes cavity 615. System assembly 610 also can comprise similar elements as system assembly 110, such as power supply circuity 113 and decoupling capacitors 112, among other elements.

FIG. 7 includes a side view 700 to illustrate a stackup among motherboard 611, package assembly 120, integrated circuit device 130, and capacitors 140. At a bottom of the stackup in FIG. 7, system assembly 610 is shown having one or more perimeter decoupling capacitors 112 and power supply circuitry 113. Further circuity can be included in system assembly 610, such as memory, storage, peripherals, power distribution circuity, and other similar elements. These are not shown in FIG. 7 for clarity. Integrated circuit device 130 comprises a semiconductor die which is bonded to carrier circuit board 121 of package assembly 120. This configuration might comprise a flip-chip configuration, although other configurations are possible. Solder balls 271 couple integrated circuit device 130 to carrier circuit board 121, along with other circuitry which might include perimeter decoupling capacitors 122.

Chip-scale assembly 750 is shown in FIG. 7 as comprising integrated circuit 130, carrier circuit board 121, and capacitors 140, along with associated solder balls 271 and 773. Furthermore, capacitors 140 are coupled to a bottom size of carrier circuit board 121 via solder balls 774 and conductive pads 624. Various potting, such as epoxy, filler, thermal compound, or other material can be deposited between capacitors 140. This potting can be added prior to mating of chip-scale assembly 750 to motherboard 611. Potting can aid in mechanical holding and stability of capacitors 140 once capacitors 140 are bonded or soldered to the bottom size of carrier circuit board 121. Gaps between capacitors 140 can accept portions of potting for further mechanical stability. Potting can also aid solder reflow operations when mating chip-scale assembly 750 to motherboard 611 via solder balls 773, such as to prevent movement or de-soldering of capacitors 140 from conductive pads 624 or solder balls 774.

Placement of capacitors 140 on carrier circuit board 121 can correspond to various areas of integrated circuit device 130 that can benefit from decoupling capacitance, due in part to having dynamic operation with high power demand and susceptibility to voltage transients. Example areas of integrated circuit device 130 include processing cores, graphics cores, input/output cores, memory bus cores, and other similar elements. Some areas of the device may be somewhat immune from such concerns, due to either low power demands overall or having consistent power demand that varies little and thus corresponds to low power supply noise.

Advantageously, the stackup formed by chip-scale assembly 750 provides for decoupling capacitance of capacitors 140 near to affected circuity of integrated circuit 130. Decoupling capacitors 140 thus become more effective at reducing high-frequency transients in power lines and power domains of integrated circuit device 130. Moreover, since correspondingly short links are needed between capacitors 140 and integrated circuit device 130, such as compared to capacitors 112 and 122, inductance between capacitors 140 and integrated circuit device 130 is also minimized

Cavity 615 which is formed into motherboard 611 comprises a partial reduction in a thickness of motherboard 611, such as by milling, drilling, etching, or routing out one or more circuit board layers. Cavity 615 can still contain one or more substrate layers, which may comprise routable conductive layers and insulating layers. A depth of cavity 615 can correspond to a vertical height or stackup of capacitors 140 when mated to carrier circuit board 121, or can be of other depths to accommodate other elements. Together, assembly 750 can form a discrete assembly which can be mounted directly to motherboard 611 even though capacitors 140 protrude below carrier circuit board 121. Motherboard 611 thus accommodates decoupling capacitors 140 in a protected pocket formed by cavity 615, which can be filled with potting material to provide for enhanced mechanical stability, thermal performance, and tamper resistance. Although a single cavity 615 is included, other examples might have more than one cavity, and each cavity might accommodate one or more of capacitors 140.

A final assembly having system assembly 610, chip-scale assembly 750, and any applicable heat sinks would provide substantially improved power supply decoupling for integrated circuit device 130 that allows for improved performance and/or reduced power supply voltages due to decreased power supply noise. This can also lead to improved circuit operating voltage minimum (Vmin) values by having less dynamic variation in voltage levels provided to the individual power domains. The closely-positioned decoupling capacitance can lead to better dynamic performance on any associated voltage lines and voltage domains of integrated circuit device 130, allowing for lower operating voltages for the domains of integrated circuit device 130, and hence lower power. Voltage optimization techniques might be controlled by power supply circuitry 113 to reduce supply voltages to integrated circuit device 130. These voltage optimization techniques can also benefit from the closely-positioned decoupling capacitances shown herein. Specifically, a reduced magnitude of transient effects on voltage domains from the close decoupling capacitance can also correspond to reduced voltage levels needed to be supplied to a given circuit.

In addition to capacitors 140, other circuitry can be placed into cavity 615 formed by motherboard 611. This other circuitry can include passive and active electrical components, power supply circuitry, voltage lowering circuity for integrated circuit device 130, various integrated circuitry, resistors, inductors, transistors, and other similar circuitry.

To illustrate power flow through a final assembly having chip-scale assembly 750 mated to system assembly 610, example power flow 701 is shown. Power flow 701 can be for any exemplary power link, voltage domain, ground, or reference voltage provided to integrated circuit device 130. Input power/voltage is received from an external power source, conditioned and converted by power supply circuitry 113 and provided to circuit board traces/planes of motherboard 611. For example, V_{DD} and ground for integrated circuit device 130 can be represented by power flow 701 and routed through one or more solder balls in FIG. 7. Power flow 701 can be replicated for more than one instance of V_{DD} and ground for individual power domains of integrated circuit device 130. One or more conductive paths formed by solder balls 773 and associated conductive pads route power flow 701 through conductive elements of carrier circuit board 121 to reach integrated circuit device 130. In this example, power flow 701 does not pass through terminals of capacitors 140, although other power may flow through terminals of capacitors which is related to decoupling operations. Instead, capacitors tap into power traces, planes, or vias of carrier circuit board 121. In many of the examples herein, however, power flow is provided though terminals of decoupling capacitors.

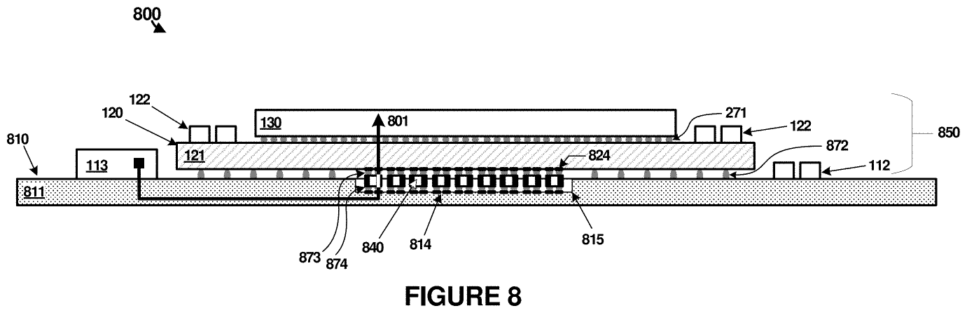

To illustrate elements from FIGS. 6 and 7 with power pass-through capacitors, FIG. 8 is presented. FIG. 8 illustrates side view 800 of an integrated circuit assembly having a motherboard 811 with cavity 815 and pass-through decoupling capacitors 840 in an implementation. Although similar elements as found in FIGS. 1-7 are shown in FIG. 8, it should be understood that different elements can instead be included. In FIG. 8, an arrangement is provided which routes at least a portion of the power and grounding for integrated circuit device 130 through terminals of decoupling capacitors 840. Conductive pads 814 are provided on motherboard 811 of system assembly 810 which couple to traces, planes, or vias which carry one or more voltages and reference potentials for integrated circuit device 130. These one or more voltages and reference potentials can be supplied by power supply circuitry 113.

These power pass-through features shown in FIG. 8 comprise coupling at least a portion of the power supplied to integrated circuit device 130 through terminals of capacitors 840. Advantageously, a more direct route of power and ground connections is provided to integrated circuit device 130, with decoupling capacitance very near to power input terminals of integrated circuit device 130. Moreover, the conductive nature of the power pass-through features can aid in thermal conduction via metal elements for integrated circuit device 130. Tighter tolerances on a stackup or height between carrier circuit board 121 and motherboard 811 might be needed, along with more accurate control over placement and positioning of capacitors 840. Capacitors 840 also are coupled to conductive pads of two circuit boards, namely conductive pads 824 of carrier circuit board 121 and conductive pads 814 of motherboard 811. However, the performance advantages of such an arrangement can outweigh any increased manufacturing complexity.

To aid mating of capacitors 840 to both motherboard 811 and carrier circuit board 121, a pre-assembled chip-scale assembly 850 can be produced. This chip-scale assembly 850 comprises integrated circuit device 130 coupled to carrier circuit board 121. Capacitors 840 can then be coupled to carrier circuit board 121 using solder reflow processes to couple capacitors 840 to conductive pads 824 on the ‘underside’ or ‘landside’ of carrier circuit board 121. Then, chip-scale assembly 850 can be mated to motherboard 811. Various potting or epoxy filler might be placed between capacitors 840 before mating to motherboard 811 to mechanically secure capacitors 840 after soldering is completed. Thus, when a secondary solder reflow process occurs to mate chip-scale assembly 850 to motherboard 811, capacitors 840 can remain secure in the soldered locations without danger of movement or inadvertent de-soldering. Other techniques can be employed, such as using solder materials with different melting points for different sets of solder balls

Motherboard 811 can comprise similar elements and configurations as system circuit board 111. However, motherboard 811 includes conductive pads 814 and cavity 815. System assembly 810 also can comprise similar elements as system assembly 110, such as power supply circuity 113 and decoupling capacitors 112, among other elements. Cavity 815 which is formed into motherboard 811 comprises a partial reduction in a thickness of motherboard 811, such as by milling, drilling, etching, or routing out one or more circuit board layers. Cavity 815 can still contain one or more substrate layers, which may comprise routable conductive layers and insulating layers. A depth of cavity 815 can correspond to a vertical height or stackup of capacitors 840 when mated between carrier circuit board 121 and motherboard 811, or can be of other depths to accommodate other elements. Together, assembly 850 can form a discrete assembly which can be mounted directly to motherboard 811 even though capacitors 840 protrude below carrier circuit board 121. Motherboard 811 thus accommodates decoupling capacitors 840 in a protected pocket formed by cavity 815, which can be filled with potting material to provide for enhanced mechanical stability, thermal performance, and tamper resistance.

Capacitors 840 can comprise similar elements as described herein for capacitors 140 or 540. However, variations in capacitors 840 can be established to account for soldering terminals to two different circuit boards. Moreover, a thickness or stackup height of capacitors 840 might vary to match a desired stackup within cavity 815 or formed by carrier circuit board 121 and motherboard 811. Conductive spacers for terminals of capacitors 840 other similar features might be employed when capacitors are too thin vertically to fit properly in the vertical stackup. When an integrated capacitance device is employed, such as a semiconductor die with individual capacitance elements formed thereon, then this capacitance device might have conductive pads on both surfaces of the die, along with any associated internal power and ground coupling features, such as routes, planes, through-silicon vias. A thickness of the integrated capacitance device might be sized according to a vertical stackup within cavity 815 or formed by carrier circuit board 121 and motherboard 811.

In addition to capacitors 840, other circuitry can be placed into cavity 815 formed by motherboard 811. This other circuitry can include passive and active electrical components, power supply circuitry, voltage lowering circuity for integrated circuit device 130, various integrated circuitry, resistors, inductors, transistors, and other similar circuitry.

To illustrate power flow through a final assembly having chip-scale assembly 850 mated to system assembly 810, example power flow 801 is shown. Power flow 801 can be for any exemplary power link, voltage domain, ground, or reference voltage provided to integrated circuit device 130. Input power/voltage is received from an external power source, conditioned and converted by power supply circuitry 113 and provided to circuit board traces/planes of motherboard 811. For example, VDD and ground for integrated circuit device 130 can be represented by power flow 801 and routed through one or more terminals of capacitors 840. Power flow 801 can be replicated for more than one instance of V_{DD} and ground for individual power domains of integrated circuit device 130. One or more conductive paths formed by conductive pads 814, solder balls 874, terminals of selected capacitors 840, solder balls 873, and conductive pads 824 route power flow 801 through conductive elements of carrier circuit board 121 to reach integrated circuit device 130. In this example, power flow 801 passes through terminals of capacitors 840. A portion of the power flow may also be routed through solder balls 872.

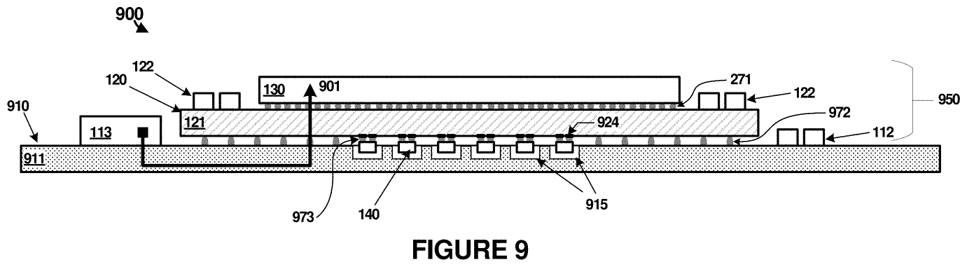

FIG. 9 is presented to illustrate an alternative arrangement of elements seen in FIGS. 6 and 7. Specifically, FIG. 9 illustrates side view 900 of an integrated circuit assembly having multiple cavities 915 formed into motherboard 911 to accommodate decoupling capacitors 140 in an implementation. Capacitors 140 are coupled to conductive pads 924 of carrier circuit board 121. Motherboard 911 can comprise similar elements and configurations as system circuit board 611. However, motherboard 611 includes single cavity 615, and motherboard 911 includes multiple cavities 915. System assembly 910 also can comprise similar elements as system assembly 610, such as power supply circuity 113 and decoupling capacitors 112, among other elements.

FIG. 9 includes a side view 900 to illustrate a stackup among motherboard 911, package assembly 120, integrated circuit device 130, and capacitors 140. At a bottom of the stackup in FIG. 9, system assembly 910 is shown having one or more perimeter decoupling capacitors 112 and power supply circuitry 113. Further circuity can be included in system assembly 910, such as memory, storage, peripherals, power distribution circuity, and other similar elements. These are not shown in FIG. 9 for clarity. Integrated circuit device 130 comprises a semiconductor die which is bonded to carrier circuit board 121 of package assembly 120. This configuration might comprise a flip-chip configuration, although other configurations are possible. Solder balls 271 couple integrated circuit device 130 to carrier circuit board 121, along with other circuitry which might include perimeter decoupling capacitors 122.

Chip-scale assembly 950 is shown in FIG. 9 as comprising integrated circuit 130, carrier circuit board 121, and capacitors 140, along with associated solder balls 271 and 972. Furthermore, capacitors 140 are coupled to a bottom size of carrier circuit board 121 via solder balls 973 and conductive pads 924. Various potting, such as epoxy, filler, thermal compound, or other material can be deposited in individual cavities 915. This potting can be added prior to mating of chip-scale assembly 950 to motherboard 911. Potting can aid in mechanical holding and stability of capacitors 140 once capacitors 140 are bonded or soldered to the bottom size of carrier circuit board 121. Gaps between capacitors 140 and walls of cavities 915 can accept portions of potting for further mechanical stability. Potting can also aid solder reflow operations when mating chip-scale assembly 950 to motherboard 911 via solder balls 972, such as to prevent movement or de-soldering of capacitors 140 from conductive pads 924 or solder balls 973.

Placement of capacitors 140 on carrier circuit board 121 can correspond to various areas of integrated circuit device 130 that can benefit from decoupling capacitance, due in part to having dynamic operation with high power demand and susceptibility to voltage transients. Example areas of integrated circuit device 130 include processing cores, graphics cores, input/output cores, memory bus cores, and other similar elements. Some areas of the device may be somewhat immune from such concerns, due to either low power demands overall or having consistent power demand that varies little and thus corresponds to low power supply noise.

Advantageously, the stackup formed by chip-scale assembly 950 provides for decoupling capacitance of capacitors 140 near to affected circuity of integrated circuit 130. Decoupling capacitors 140 thus become more effective at reducing high-frequency transients in power lines and power domains of integrated circuit device 130. Moreover, since correspondingly short links are needed between capacitors 140 and integrated circuit device 130, such as compared to capacitors 112 and 122, inductance between capacitors 140 and integrated circuit device 130 is also minimized

Cavities 915 which are formed into motherboard 911 each comprise a partial reduction in a thickness of motherboard 911, such as by milling, drilling, etching, or routing out one or more circuit board layers. Cavities 915 can each still contain one or more substrate layers, which may comprise routable conductive layers and insulating layers. A depth of cavities 915 can correspond to a vertical height or stackup of capacitors 140 when mated to carrier circuit board 121, or can be of other depths to accommodate other elements. Together, assembly 950 can form a discrete assembly which can be mounted directly to motherboard 911 even though capacitors 140 protrude below carrier circuit board 121. Motherboard 911 thus accommodates decoupling capacitors 140 in protected pockets formed by cavities 915, which can be filled with potting material to provide for enhanced mechanical stability, thermal performance, and tamper resistance. Each of cavities 915 might accommodate one or more of capacitors 140. Moreover, the individual cavities 915 might provide for improved manufacturability than a single large cavity 615 in FIGS. 6 and 7.

A final assembly having system assembly 910, chip-scale assembly 950, and any applicable heat sinks would provide substantially improved power supply decoupling for integrated circuit device 130 that allows for improved performance and/or reduced power supply voltages due to decreased power supply noise. This can also lead to improved circuit operating voltage minimum (Vmin) values by having less dynamic variation in voltage levels provided to the individual power domains. The closely-positioned decoupling capacitance can lead to better dynamic performance on any associated voltage lines and voltage domains of integrated circuit device 130, allowing for lower operating voltages for the domains of integrated circuit device 130, and hence lower power. Voltage optimization techniques might be controlled by power supply circuitry 113 to reduce supply voltages to integrated circuit device 130. These voltage optimization techniques can also benefit from the closely-positioned decoupling capacitances shown herein. Specifically, a reduced magnitude of transient effects on voltage domains from the close decoupling capacitance can also correspond to reduced voltage levels needed to be supplied to a given circuit.

In addition to capacitors 140, other circuitry can be placed into cavities 915 formed by motherboard 911. This other circuitry can include passive and active electrical components, power supply circuitry, voltage lowering circuity for integrated circuit device 130, various integrated circuitry, resistors, inductors, transistors, and other similar circuitry. Segregation of components into individual ones of cavities 915 can also aid in reduction of cross-talk, electromagnetic interference among components mounted into different ones of cavities 915.

To illustrate power flow through a final assembly having chip-scale assembly 950 mated to system assembly 910, example power flow 901 is shown. Power flow 901 can be for any exemplary power link, voltage domain, ground, or reference voltage provided to integrated circuit device 130. Input power/voltage is received from an external power source, conditioned and converted by power supply circuitry 113 and provided to circuit board traces/planes of motherboard 911. For example, V_{DD} and ground for integrated circuit device 130 can be represented by power flow 901 and routed through one or more solder balls in FIG. 9. Power flow 901 can be replicated for more than one instance of V_{DD} and ground for individual power domains of integrated circuit device 130. One or more conductive paths formed by solder balls 972 and associated conductive pads route power flow 901 through conductive elements of carrier circuit board 121 to reach integrated circuit device 130. In this example, power flow 901 does not pass through terminals of capacitors 140, although other power may flow through terminals of capacitors which is related to decoupling operations. Instead, capacitors tap into power traces, planes, or vias of carrier circuit board 121. In many of the examples herein, however, power flow is provided though terminals of decoupling capacitors.

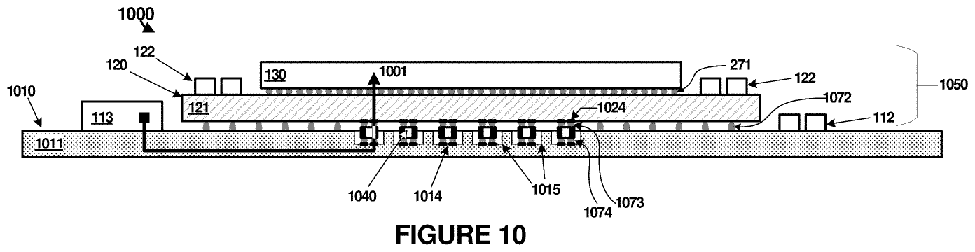

FIG. 10 is presented to illustrate an alternative arrangement of elements seen in FIG. 8. Specifically, FIG. 10 illustrates side view 1000 of an integrated circuit assembly having multiple cavities 1015 formed into motherboard 1011 to accommodate pass-through decoupling capacitors 1040 in an implementation. Although similar elements as found in FIGS. 1-9 are shown in FIG. 10, it should be understood that different elements can instead be included. In FIG. 10, an arrangement is provided which routes at least a portion of the power and grounding for integrated circuit device 130 through terminals of decoupling capacitors 1040.

Motherboard 1011 can comprise similar elements and configurations as system circuit board 811. However, motherboard 811 includes single cavity 815, and motherboard 1011 includes multiple cavities 1015. System assembly 1010 also can comprise similar elements as system assembly 110, such as power supply circuity 113 and decoupling capacitors 112, among other elements. Cavities 1015, which are formed into motherboard 1011, each comprise a partial reduction in a thickness of motherboard 1011, such as by milling, drilling, etching, or routing out one or more circuit board layers. Cavities 1015 can each still contain one or more substrate layers, which may comprise routable conductive layers and insulating layers. A depth of cavities 1015 can correspond to a vertical height or stackup of capacitors 1040 when mated between carrier circuit board 121 and motherboard 1011, or can be of other depths to accommodate other elements. Together, assembly 1050 can form a discrete assembly which can be mounted directly to motherboard 1011 even though capacitors 1040 protrude below carrier circuit board 121. Motherboard 1011 thus accommodates decoupling capacitors 1040 in protected pockets formed by cavities 1015, which can be filled with potting material to provide for enhanced mechanical stability, thermal performance, and tamper resistance. Each of cavities 1015 might accommodate one or more of capacitors 140. Moreover, the individual cavities 1015 might provide for improved manufacturability than a single large cavity 815 in FIG. 8.

These power pass-through features shown in FIG. 10 comprise coupling at least a portion of the power supplied to integrated circuit device 130 through terminals of capacitors 1040. Advantageously, a more direct route of power and ground connections is provided to integrated circuit device 130, with decoupling capacitance very near to power input terminals of integrated circuit device 130. Moreover, the conductive nature of the power pass-through features can aid in thermal conduction via metal elements for integrated circuit device 130. Tighter tolerances on a stackup or height between carrier circuit board 121 and motherboard 1011 might be needed, along with more accurate control over placement and positioning of capacitors 1040. Capacitors 1040 also are coupled to conductive pads of two circuit boards, namely conductive pads 1024 of carrier circuit board 121 and conductive pads 1014 of motherboard 1011. However, the performance advantages of such an arrangement can outweigh any increased manufacturing complexity.

To aid mating of capacitors 1040 to both motherboard 1011 and carrier circuit board 121, a pre-assembled chip-scale assembly 1050 can be produced. This chip-scale assembly 1050 comprises integrated circuit device 130 coupled to carrier circuit board 121. Capacitors 1040 can then be coupled to carrier circuit board 121 using solder reflow processes to couple capacitors 1040 to conductive pads 1024 on the ‘underside’ or ‘landside’ of carrier circuit board 121. Then, chip-scale assembly 1050 can be mated to motherboard 1011. Various potting, such as epoxy, filler, thermal compound, or other material can be deposited in individual cavities 1015. This potting can be added prior to mating of chip-scale assembly 1050 to motherboard 1011. Potting can aid in mechanical holding and stability of capacitors 1040 once capacitors 1040 are bonded or soldered to the bottom size of carrier circuit board 121. Gaps between capacitors 1040 and walls of cavities 1015 can accept portions of potting for further mechanical stability. Potting can also aid solder reflow operations when mating chip-scale assembly 1050 to motherboard 1011 via solder balls 1072, such as to prevent movement or de-soldering of capacitors 1040 from conductive pads 1024 or solder balls 1073. Thus, when a secondary solder reflow process occurs to mate chip-scale assembly 1050 to motherboard 1011, capacitors 1040 can remain secure in the soldered locations without danger of movement or inadvertent de-soldering. Other techniques can be employed, such as using solder materials with different melting points for different sets of solder balls.

Capacitors 1040 can comprise similar elements as described herein for capacitors 140 or 540. However, variations in capacitors 1040 can be established to account for soldering terminals to two different circuit boards. Moreover, a thickness or stackup height of capacitors 1040 might vary to match a desired stackup within cavities 1015 or formed by carrier circuit board 121 and motherboard 1011. Conductive spacers for terminals of capacitors 1040 other similar features might be employed when capacitors are too thin vertically to fit properly in the vertical stackup. When an integrated capacitance device is employed, such as a semiconductor die with individual capacitance elements formed thereon, then this capacitance device might have conductive pads on both surfaces of the die, along with any associated internal power and ground coupling features, such as routes, planes, through-silicon vias. A thickness of the integrated capacitance device might be sized according to a vertical stackup within cavities 1015 or formed by carrier circuit board 121 and motherboard 1011.

In addition to capacitors 1040, other circuitry can be placed into cavities 1015 formed by motherboard 1011. This other circuitry can include passive and active electrical components, power supply circuitry, voltage lowering circuity for integrated circuit device 130, various integrated circuitry, resistors, inductors, transistors, and other similar circuitry. Segregation of components into individual ones of cavities 1015 can also aid in reduction of cross-talk, electromagnetic interference among components mounted into different ones of cavities 1015.

To illustrate power flow through a final assembly having chip-scale assembly 1050 mated to system assembly 1010, example power flow 1001 is shown. Power flow 1001 can be for any exemplary power link, voltage domain, ground, or reference voltage provided to integrated circuit device 130. Input power/voltage is received from an external power source, conditioned and converted by power supply circuitry 113 and provided to circuit board traces/planes of motherboard 1011. For example, V_{DD} and ground for integrated circuit device 130 can be represented by power flow 1001 and routed through one or more terminals of capacitors 1040. Power flow 1001 can be replicated for more than one instance of V_{DD} and ground for individual power domains of integrated circuit device 130. One or more conductive paths formed by conductive pads 1014, solder balls 1074, terminals of selected capacitors 1040, solder balls 1073, and conductive pads 1024 route power flow 1001 through conductive elements of carrier circuit board 121 to reach integrated circuit device 130. In this example, power flow 1001 passes through terminals of capacitors 1040. A portion of the power flow may also be routed through solder balls 1072.

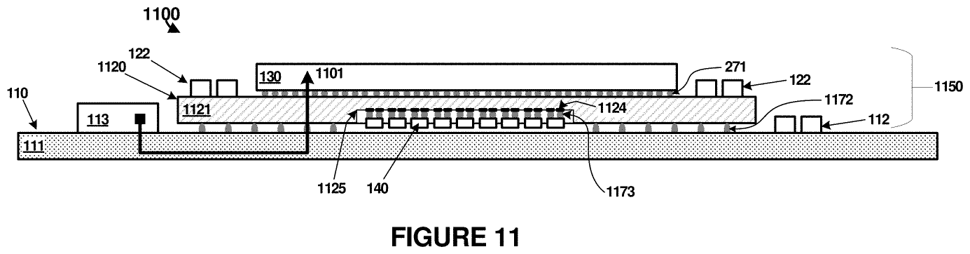

FIG. 11 illustrates side view 1100 of an integrated circuit assembly having carrier circuit board 1121 with cavity 1125 in an implementation. FIG. 11 illustrates an alternative arrangement than those seen in Figures herein which have a cavity or cavities in an underlying system circuit board or motherboard. Although similar elements as found in FIGS. 1-10 are shown in FIG. 11, it should be understood that different elements can instead be included. In FIG. 11, an arrangement is provided with cavity 1125 in carrier circuit board 1121 of package assembly 1120 to allow for a vertical stackup of decoupling capacitors 140 below a shadow or footprint of integrated circuit device 130 on package assembly 1120. The terms underneath or below refer to a side of carrier circuit board 1121 opposite the side onto which integrated circuit device 130 is mounted or coupled. In some examples, this opposite side can be referred to as a land-side. The integrated circuit assembly in FIG. 11 lacks an interposer circuit board or associated interposer assembly.

FIG. 11 illustrates side view 1100 of an integrated circuit assembly having cavity 1125 formed into carrier circuit board 1121 to accommodate decoupling capacitors 140. Capacitors 140 are coupled to conductive pads 1124 of carrier circuit board 1121. Side view 1100 illustrates a stackup among system circuit board 111, package assembly 1120, integrated circuit device 130, and capacitors 140. At a bottom of the stackup in FIG. 11, system assembly 110 is shown having one or more perimeter decoupling capacitors 112 and power supply circuitry 113. Further circuity can be included in system assembly 110, such as memory, storage, peripherals, power distribution circuity, and other similar elements. These are not shown in FIG. 11 for clarity. Integrated circuit device 130 comprises a semiconductor die which is bonded to carrier circuit board 1121 of package assembly 1120. This configuration might comprise a flip-chip configuration, although other configurations are possible. Solder balls 271 couple integrated circuit device 130 to carrier circuit board 1121, along with other circuitry which might include perimeter decoupling capacitors 122.

Chip-scale assembly 1150 is shown in FIG. 11 as comprising integrated circuit 130, carrier circuit board 1121, and capacitors 140, along with associated solder balls 271 and 1172. Furthermore, capacitors 140 are coupled to a bottom size of carrier circuit board 1121 via solder balls 1173 and conductive pads 1124. Various potting, such as epoxy, filler, thermal compound, or other material can be deposited between capacitors 140. This potting can be added prior to mating of chip-scale assembly 1150 to motherboard 111. Potting can aid in mechanical holding and stability of capacitors 140 once capacitors 140 are bonded or soldered to the bottom size of carrier circuit board 1121. Gaps between capacitors 140 can accept portions of potting for further mechanical stability. Potting can also aid solder reflow operations when mating chip-scale assembly 1150 to motherboard 111 via solder balls 1172, such as to prevent movement or de-soldering of capacitors 140 from conductive pads 1124 or solder balls 1173.

Placement of capacitors 140 on carrier circuit board 1121 can correspond to various areas of integrated circuit device 130 that can benefit from decoupling capacitance, due in part to having dynamic operation with high power demand and susceptibility to voltage transients. Example areas of integrated circuit device 130 include processing cores, graphics cores, input/output cores, memory bus cores, and other similar elements. Some areas of the device may be somewhat immune from such concerns, due to either low power demands overall or having consistent power demand that varies little and thus corresponds to low power supply noise.

Advantageously, the stackup formed by chip-scale assembly 1150 provides for decoupling capacitance of capacitors 140 near to affected circuity of integrated circuit 130. Decoupling capacitors 140 thus become more effective at reducing high-frequency transients in power lines and power domains of integrated circuit device 130. Moreover, since correspondingly short links are needed between capacitors 140 and integrated circuit device 130, such as compared to capacitors 112 and 122, inductance between capacitors 140 and integrated circuit device 130 is also minimized.

Cavity 1125 which is formed into carrier circuit board 1121 comprises a partial reduction in a thickness of carrier circuit board 1121, such as by milling, drilling, etching, or routing out one or more circuit board layers. Cavity 1125 can still contain one or more substrate layers, which may comprise routable conductive layers and insulating layers. A depth of cavity 1125 can correspond to a vertical height or stackup of capacitors 140 when mated to system circuit board 111, or can be of other depths to accommodate other elements. Together, assembly 1150 can form a discrete assembly which can be mounted directly to motherboard 111 by providing for a recessed mounting of capacitors 140 to prevent excessive protrusion below carrier circuit board 1121. Carrier circuit board 1121 thus accommodates decoupling capacitors 140 in a protected pocket formed by cavity 1125, which can be filled with potting material to provide for enhanced mechanical stability, thermal performance, and tamper resistance. Although a single cavity 1125 is included, other examples might have more than one cavity, and each cavity might accommodate one or more of capacitors 140.

A final assembly having system assembly 110, chip-scale assembly 1150, and any applicable heat sinks would provide substantially improved power supply decoupling for integrated circuit device 130 that allows for improved performance and/or reduced power supply voltages due to decreased power supply noise. This can also lead to improved circuit operating voltage minimum (Vmin) values by having less dynamic variation in voltage levels provided to the individual power domains. The closely-positioned decoupling capacitance can lead to better dynamic performance on any associated voltage lines and voltage domains of integrated circuit device 130, allowing for lower operating voltages for the domains of integrated circuit device 130, and hence lower power. Voltage optimization techniques might be controlled by power supply circuitry 113 to reduce supply voltages to integrated circuit device 130. These voltage optimization techniques can also benefit from the closely-positioned decoupling capacitances shown herein. Specifically, a reduced magnitude of transient effects on voltage domains from the close decoupling capacitance can also correspond to reduced voltage levels needed to be supplied to a given circuit. Also, similar techniques can be employed for reduction of any internally-generated voltages of integrated circuit device 130.

In addition to capacitors 140, other circuitry can be placed into cavity 1125 formed into carrier circuit board 1121. This other circuitry can include passive and active electrical components, power supply circuitry, voltage lowering circuity for integrated circuit device 130, various integrated circuitry, resistors, inductors, transistors, and other similar circuitry.

To illustrate power flow through a final assembly having chip-scale assembly 1150 mated to system assembly 110, example power flow 1101 is shown. Power flow 1101 can be for any exemplary power link, voltage domain, ground, or reference voltage provided to integrated circuit device 130. Input power/voltage is received from an external power source, conditioned and converted by power supply circuitry 113 and provided to circuit board traces/planes of system circuit board 111. For example, V_{DD} and ground for integrated circuit device 130 can be represented by power flow 1101 and routed through one or more solder balls in FIG. 11. Power flow 1101 can be replicated for more than one instance of V_{DD} and ground for individual power domains of integrated circuit device 130. One or more conductive paths formed by solder balls 1172 and associated conductive pads route power flow 1101 through conductive elements of carrier circuit board 1121 to reach integrated circuit device 130. In this example, power flow 1101 does not pass through terminals of capacitors 140, although other power may flow through terminals of capacitors which is related to decoupling operations. Instead, capacitors tap into power traces, planes, or vias of carrier circuit board 1121. In many of the examples herein, however, power flow is provided though terminals of decoupling capacitors.

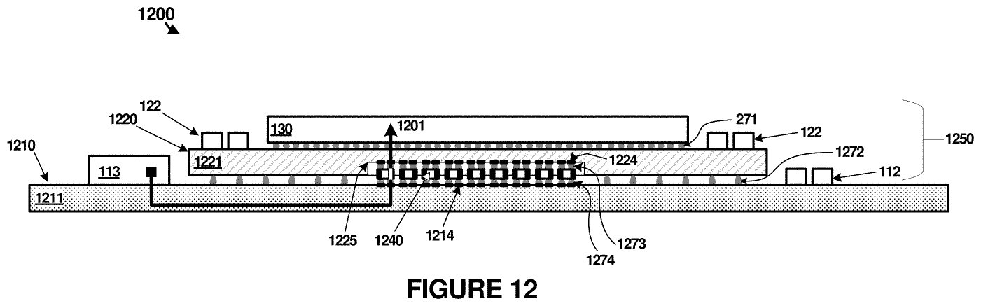

To illustrate elements from FIG. 11 with power pass-through capacitors, FIG. 12 is presented. FIG. 12 illustrates side view 1200 of an integrated circuit assembly having a carrier circuit board 1221 with cavity 1225 and pass-through decoupling capacitors 1240 in an implementation. Although similar elements as found in FIGS. 1-11 are shown in FIG. 12, it should be understood that different elements can instead be included. In FIG. 12, an arrangement is provided which routes at least a portion of the power and grounding for integrated circuit device 130 through terminals of decoupling capacitors 1240. Conductive pads 1214 are provided on motherboard 1211 of system assembly 1210 which couple to traces, planes, or vias which carry one or more voltages and reference potentials for integrated circuit device 130. These one or more voltages and reference potentials can be supplied by power supply circuitry 113.

These power pass-through features shown in FIG. 12 comprise coupling at least a portion of the power supplied to integrated circuit device 130 through terminals of capacitors 1240. Advantageously, a more direct route of power and ground connections is provided to integrated circuit device 130, with decoupling capacitance very near to power input terminals of integrated circuit device 130. Moreover, the conductive nature of the power pass-through features can aid in thermal conduction via metal elements for integrated circuit device 130. Tighter tolerances on a stackup or height between carrier circuit board 1221 and motherboard 1211 might be needed, along with more accurate control over placement and positioning of capacitors 1240. Capacitors 1240 also are coupled to conductive pads of two circuit boards, namely conductive pads 1224 of carrier circuit board 1221 and conductive pads 1214 of motherboard 1211. However, the performance advantages of such an arrangement can outweigh any increased manufacturing complexity.

To aid mating of capacitors 1240 to both motherboard 1211 and carrier circuit board 1221, a pre-assembled chip-scale assembly 1250 can be produced. This chip-scale assembly 1250 comprises integrated circuit device 130 coupled to carrier circuit board 1221. Capacitors 1240 can then be coupled to carrier circuit board 1221 using solder reflow processes to couple capacitors 1240 to conductive pads 1224 on the ‘underside’ or ‘landside’ of carrier circuit board 1221. Then, chip-scale assembly 1250 can be mated to motherboard 1211. Various potting or epoxy filler might be placed between capacitors 1240 before mating to motherboard 1211 to mechanically secure capacitors 1240 after soldering is completed. Thus, when a secondary solder reflow process occurs to mate chip-scale assembly 1250 to motherboard 1211, capacitors 1240 can remain secure in the soldered locations without danger of movement or inadvertent de-soldering. Other techniques can be employed, such as using solder materials with different melting points for different sets of solder balls.

Motherboard 1211 can comprise similar elements and configurations as system circuit board 111. However, motherboard 1211 includes conductive pads 1214. System assembly 1210 also can comprise similar elements as system assembly 110, such as power supply circuity 113 and decoupling capacitors 112, among other elements.

Carrier circuit board 1221 can comprise similar elements and configurations as carrier circuit board 121. However, carrier circuit board 1221 includes cavity 1225 which is formed into carrier circuit board 1221. Cavity 1225 comprises a partial reduction in a thickness of carrier circuit board 1221, such as by milling, drilling, etching, or routing out one or more circuit board layers. Cavity 1225 can still contain one or more substrate layers, which may comprise routable conductive layers and insulating layers. A depth of cavity 1225 can correspond to a vertical height or stackup of capacitors 1240 when mated between carrier circuit board 1221 and motherboard 1211, or can be of other depths to accommodate other elements. Together, assembly 1250 can form a discrete assembly which can be mounted directly to motherboard 1211 by providing for a recessed mounting of capacitors 1240 to prevent excessive protrusion below carrier circuit board 1221. Carrier circuit board 1221 thus accommodates decoupling capacitors 1240 in a protected pocket formed by cavity 1225, which can be filled with potting material to provide for enhanced mechanical stability, thermal performance, and tamper resistance. Although a single cavity 1225 is included, other examples might have more than one cavity, and each cavity might accommodate one or more of capacitors 1240.

Capacitors 1240 can comprise similar elements as described herein for capacitors 140 or 540. However, variations in capacitors 1240 can be established to account for soldering terminals to two different circuit boards. Moreover, a thickness or stackup height of capacitors 1240 might vary to match a desired stackup within cavity 1225 formed by carrier circuit board 1221. Conductive spacers for terminals of capacitors 1240 other similar features might be employed when capacitors are too thin vertically to fit properly in the vertical stackup. When an integrated capacitance device is employed, such as a semiconductor die with individual capacitance elements formed thereon, then this capacitance device might have conductive pads on both surfaces of the die, along with any associated internal power and ground coupling features, such as routes, planes, through-silicon vias. A thickness of the integrated capacitance device might be sized according to a vertical stackup within cavity 1225 or formed by carrier circuit board 1221 and motherboard 1211.

In addition to capacitors 1240, other circuitry can be placed into cavity 1225 formed by carrier circuit board 1221. This other circuitry can include passive and active electrical components, power supply circuitry, voltage lowering circuity for integrated circuit device 130, various integrated circuitry, resistors, inductors, transistors, and other similar circuitry.

To illustrate power flow through a final assembly having chip-scale assembly 1250 mated to system assembly 1210, example power flow 1201 is shown. Power flow 1201 can be for any exemplary power link, voltage domain, ground, or reference voltage provided to integrated circuit device 130. Input power/voltage is received from an external power source, conditioned and converted by power supply circuitry 113 and provided to circuit board traces/planes of motherboard 1211. For example, V_{DD} and ground for integrated circuit device 130 can be represented by power flow 1201 and routed through one or more terminals of capacitors 1240. Power flow 1201 can be replicated for more than one instance of V_{DD} and ground for individual power domains of integrated circuit device 130. One or more conductive paths formed by conductive pads 1214, solder balls 1274, terminals of selected capacitors 1240, solder balls 1273, and conductive pads 1224 route power flow 1201 through conductive elements of carrier circuit board 1221 to reach integrated circuit device 130. In this example, power flow 1201 passes through terminals of capacitors 1240. A portion of the power flow may also be routed through solder balls 1272.

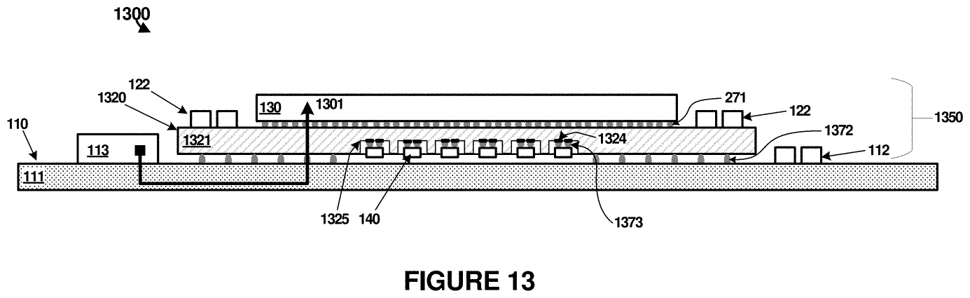

FIG. 13 illustrates side view 1300 of an integrated circuit assembly having carrier circuit board 1321 with multiple cavities 1325 in an implementation. FIG. 13 illustrates an alternative arrangement than those seen in Figures herein which have a cavity or cavities in an underlying system circuit board or motherboard. Moreover, FIG. 13 illustrates an alternative arrangement from FIG. 11 which only has a single cavity 1125 in carrier circuit board 1121. Although similar elements as found in FIGS. 1-12 are shown in FIG. 13, it should be understood that different elements can instead be included. In FIG. 13, an arrangement is provided with multiple cavities 1325 in carrier circuit board 1321 of package assembly 1320 to allow for a vertical stackup of decoupling capacitors 140 below a shadow or footprint of integrated circuit device 130 on package assembly 1320. The terms underneath or below refer to a side of carrier circuit board 1321 opposite (e.g. LSC) the side onto which integrated circuit device 130 is mounted or coupled. The integrated circuit assembly in FIG. 13 lacks an interposer circuit board or associated interposer assembly.

FIG. 13 illustrates side view 1300 of an integrated circuit assembly having cavities 1325 formed into carrier circuit board 1321 to each accommodate one or more decoupling capacitors 140. Capacitors 140 are coupled to conductive pads 1324 of carrier circuit board 1321. Side view 1300 illustrates a stackup among system circuit board 111, package assembly 1320, integrated circuit device 130, and capacitors 140. At a bottom of the stackup in FIG. 13, system assembly 110 is shown having one or more perimeter decoupling capacitors 112 and power supply circuitry 113. Further circuity can be included in system assembly 110, such as memory, storage, peripherals, power distribution circuity, and other similar elements. These are not shown in FIG. 13 for clarity. Integrated circuit device 130 comprises a semiconductor die which is bonded to carrier circuit board 1321 of package assembly 1320. This configuration might comprise a flip-chip configuration, although other configurations are possible. Solder balls 271 couple integrated circuit device 130 to carrier circuit board 1321, along with other circuitry which might include perimeter decoupling capacitors 122.

Chip-scale assembly 1350 is shown in FIG. 13 as comprising integrated circuit 130, carrier circuit board 1321, and capacitors 140, along with associated solder balls 271 and 1372. Furthermore, capacitors 140 are coupled to a bottom size of carrier circuit board 1321 via solder balls 1373 and conductive pads 1324. Various potting, such as epoxy, filler, thermal compound, or other material can be deposited between capacitors 140. This potting can be added prior to mating of chip-scale assembly 1350 to motherboard 111. Potting can aid in mechanical holding and stability of capacitors 140 once capacitors 140 are bonded or soldered to the bottom size of carrier circuit board 1321. Gaps between capacitors 140 and walls of cavities 1325 can accept portions of potting for further mechanical stability. Potting can also aid solder reflow operations when mating chip-scale assembly 1350 to motherboard 111 via solder balls 1372, such as to prevent movement or de-soldering of capacitors 140 from conductive pads 1324 or solder balls 1373.

Placement of capacitors 140 on carrier circuit board 1321 can correspond to various areas of integrated circuit device 130 that can benefit from decoupling capacitance, due in part to having dynamic operation with high power demand and susceptibility to voltage transients. Example areas of integrated circuit device 130 include processing cores, graphics cores, input/output cores, memory bus cores, and other similar elements. Some areas of the device may be somewhat immune from such concerns, due to either low power demands overall or having consistent power demand that varies little and thus corresponds to low power supply noise.

Advantageously, the stackup formed by chip-scale assembly 1350 provides for decoupling capacitance of capacitors 140 near to affected circuity of integrated circuit 130. Decoupling capacitors 140 thus become more effective at reducing high-frequency transients in power lines and power domains of integrated circuit device 130. Moreover, since correspondingly short links are needed between capacitors 140 and integrated circuit device 130, such as compared to capacitors 112 and 122, inductance between capacitors 140 and integrated circuit device 130 is also minimized

Cavities 1325, which are formed into carrier circuit board 1321, each comprise a partial reduction in a thickness of carrier circuit board 1321, such as by milling, drilling, etching, or routing out one or more circuit board layers. Cavities 1325 can each still contain one or more substrate layers, which may comprise routable conductive layers and insulating layers. A depth of cavities 1325 can correspond to a vertical height or stackup of capacitors 140 when mated to system circuit board 111, or can be of other depths to accommodate other elements. Together, assembly 1350 can form a discrete assembly which can be mounted directly to motherboard 111 by providing for a recessed mounting of capacitors 140 to prevent excessive protrusion below carrier circuit board 1321. Carrier circuit board 1321 thus accommodates decoupling capacitors 140 in protected pockets formed by cavities 1325, which can be filled with potting material to provide for enhanced mechanical stability, thermal performance, and tamper resistance. Each of cavities 1125 might accommodate one or more of capacitors 140.

A final assembly having system assembly 110, chip-scale assembly 1350, and any applicable heat sinks would provide substantially improved power supply decoupling for integrated circuit device 130 that allows for improved performance and/or reduced power supply voltages due to decreased power supply noise. This can also lead to improved circuit operating voltage minimum (Vmin) values by having less dynamic variation in voltage levels provided to the individual power domains. The closely-positioned decoupling capacitance can lead to better dynamic performance on any associated voltage lines and voltage domains of integrated circuit device 130, allowing for lower operating voltages for the domains of integrated circuit device 130, and hence lower power. Voltage optimization techniques might be controlled by power supply circuitry 113 to reduce supply voltages to integrated circuit device 130. These voltage optimization techniques can also benefit from the closely-positioned decoupling capacitances shown herein. Specifically, a reduced magnitude of transient effects on voltage domains from the close decoupling capacitance can also correspond to reduced voltage levels needed to be supplied to a given circuit.

In addition to capacitors 140, other circuitry can be placed into cavities 1325 formed into carrier circuit board 1321. This other circuitry can include passive and active electrical components, power supply circuitry, voltage lowering circuity for integrated circuit device 130, various integrated circuitry, resistors, inductors, transistors, and other similar circuitry. Segregation of components into individual ones of cavities 1325 can also aid in reduction of cross-talk, electromagnetic interference among components mounted into different ones of cavities 1325.

To illustrate power flow through a final assembly having chip-scale assembly 1350 mated to system assembly 110, example power flow 1301 is shown. Power flow 1301 can be for any exemplary power link, voltage domain, ground, or reference voltage provided to integrated circuit device 130. Input power/voltage is received from an external power source, conditioned and converted by power supply circuitry 113 and provided to circuit board traces/planes of system circuit board 111. For example, V_{DD} and ground for integrated circuit device 130 can be represented by power flow 1301 and routed through one or more solder balls in FIG. 13. Power flow 1301 can be replicated for more than one instance of V_{DD} and ground for individual power domains of integrated circuit device 130. One or more conductive paths formed by solder balls 1372 and associated conductive pads route power flow 1301 through conductive elements of carrier circuit board 1321 to reach integrated circuit device 130. In this example, power flow 1301 does not pass through terminals of capacitors 140, although other power may flow through terminals of capacitors which is related to decoupling operations. Instead, capacitors tap into power traces, planes, or vias of carrier circuit board 1321. In many of the examples herein, however, power flow is provided though terminals of decoupling capacitors.

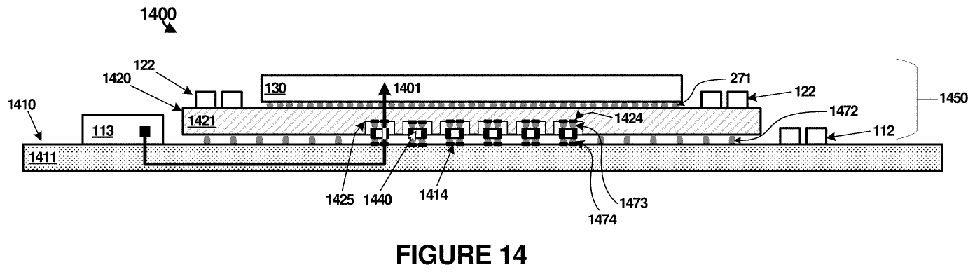

To illustrate elements from FIG. 13 with power pass-through capacitors, FIG. 14 is presented. FIG. 14 illustrates side view 1400 of an integrated circuit assembly having a carrier circuit board 1421 with multiple cavities 1425 and pass-through decoupling capacitors 1440 in an implementation. Although similar elements as found in FIGS. 1-13 are shown in FIG. 14, it should be understood that different elements can instead be included. In FIG. 14, an arrangement is provided which routes at least a portion of the power and grounding for integrated circuit device 130 through terminals of decoupling capacitors 1440. Conductive pads 1414 are provided on motherboard 1411 of system assembly 1410 which couple to traces, planes, or vias which carry one or more voltages and reference potentials for integrated circuit device 130. These one or more voltages and reference potentials can be supplied by power supply circuitry 113.

These power pass-through features shown in FIG. 14 comprise coupling at least a portion of the power supplied to integrated circuit device 130 through terminals of capacitors 1440. Advantageously, a more direct route of power and ground connections is provided to integrated circuit device 130, with decoupling capacitance very near to power input terminals of integrated circuit device 130. Moreover, the conductive nature of the power pass-through features can aid in thermal conduction via metal elements for integrated circuit device 130. Tighter tolerances on a stackup or height between carrier circuit board 1421 and motherboard 1411 might be needed, along with more accurate control over placement and positioning of capacitors 1440. Capacitors 1440 also are coupled to conductive pads of two circuit boards, namely conductive pads 1424 of carrier circuit board 1421 and conductive pads 1414 of motherboard 1411. However, the performance advantages of such an arrangement can outweigh any increased manufacturing complexity.

To aid mating of capacitors 1440 to both motherboard 1411 and carrier circuit board 1421, a pre-assembled chip-scale assembly 1450 can be produced. This chip-scale assembly 1450 comprises integrated circuit device 130 coupled to carrier circuit board 1421. Capacitors 1440 can then be coupled to carrier circuit board 1421 using solder reflow processes to couple capacitors 1440 to conductive pads 1424 on the ‘underside’ or ‘landside’ of carrier circuit board 1421. Then, chip-scale assembly 1450 can be mated to motherboard 1411. Various potting or epoxy filler might be placed within cavities 1425 and proximate to capacitors 1440 before mating to motherboard 1411 to mechanically secure capacitors 1440 after soldering is completed. Thus, when a secondary solder reflow process occurs to mate chip-scale assembly 1450 to motherboard 1411, capacitors 1440 can remain secure in the soldered locations without danger of movement or inadvertent de-soldering. Other techniques can be employed, such as using solder materials with different melting points for different sets of solder balls.

Motherboard 1411 can comprise similar elements and configurations as system circuit board 111. However, motherboard 1411 includes conductive pads 1414. System assembly 1410 also can comprise similar elements as system assembly 110, such as power supply circuity 113 and decoupling capacitors 112, among other elements.

Carrier circuit board 1421 can comprise similar elements and configurations as carrier circuit board 121. However, carrier circuit board 1421 includes multiple cavities 1425 which are formed into carrier circuit board 1421. Cavities 1425 each comprise a partial reduction in a thickness of carrier circuit board 1421, such as by milling, drilling, etching, or routing out one or more circuit board layers. Cavities 1425 can each still contain one or more substrate layers, which may comprise routable conductive layers and insulating layers. A depth of cavities 1425 can correspond to a vertical height or stackup of capacitors 1440 when mated between carrier circuit board 1421 and motherboard 1411, or can be of other depths to accommodate other elements. Together, assembly 1450 can form a discrete assembly which can be mounted directly to motherboard 1411 by providing for a recessed mounting of capacitors 1440 to prevent excessive protrusion below carrier circuit board 1421. Carrier circuit board 1421 thus accommodates decoupling capacitors 1440 in protected pockets formed by cavities 1425, which can be filled with potting material to provide for enhanced mechanical stability, thermal performance, and tamper resistance. Each of cavities 1425 might accommodate one or more of capacitors 1440.

Capacitors 1440 can comprise similar elements as described herein for capacitors 140 or 540. However, variations in capacitors 1440 can be established to account for soldering terminals to two different circuit boards. Moreover, a thickness or stackup height of capacitors 1440 might vary to match a desired stackup within cavities 1425 formed by carrier circuit board 1421. Conductive spacers for terminals of capacitors 1440 other similar features might be employed when capacitors are too thin vertically to fit properly in the vertical stackup. When an integrated capacitance device is employed, such as a semiconductor die with individual capacitance elements formed thereon, then this capacitance device might have conductive pads on both surfaces of the die, along with any associated internal power and ground coupling features, such as routes, planes, through-silicon vias. A thickness of the integrated capacitance device might be sized according to a vertical stackup within cavities 1425 or formed by carrier circuit board 1421 and motherboard 1411.

In addition to capacitors 1440, other circuitry can be placed into cavities 1425 formed by carrier circuit board 1421. This other circuitry can include passive and active electrical components, power supply circuitry, voltage lowering circuity for integrated circuit device 130, various integrated circuitry, resistors, inductors, transistors, and other similar circuitry. Segregation of components into individual ones of cavities 1425 can also aid in reduction of cross-talk, electromagnetic interference among components mounted into different ones of cavities 1425.

To illustrate power flow through a final assembly having chip-scale assembly 1450 mated to system assembly 1410, example power flow 1401 is shown. Power flow 1401 can be for any exemplary power link, voltage domain, ground, or reference voltage provided to integrated circuit device 130. Input power/voltage is received from an external power source, conditioned and converted by power supply circuitry 113 and provided to circuit board traces/planes of motherboard 1411. For example, V_{DD} and ground for integrated circuit device 130 can be represented by power flow 1401 and routed through one or more terminals of capacitors 1440. Power flow 1401 can be replicated for more than one instance of VDD and ground for individual power domains of integrated circuit device 130. One or more conductive paths formed by conductive pads 1414, solder balls 1474, terminals of selected capacitors 1440, solder balls 1473, and conductive pads 1424 route power flow 1401 through conductive elements of carrier circuit board 1421 to reach integrated circuit device 130. In this example, power flow 1401 passes through terminals of capacitors 1440. A portion of the power flow may also be routed through solder balls 1472.

Any of the aforementioned implementations can have an alternative power flow configuration than shown in the preceding Figures. Power from power supply circuitry 113 might be provided to an integrated circuit device, such as an SoC device, at a first voltage level, and one or more voltage control units within the integrated circuit device can comprise voltage regulation or voltage conversion elements that alter the first voltage level into one or more second voltage levels for one or more power domains of the integrated circuit device. These second voltage levels might be routed to internal processing cores and logic structures within the integrated circuit device, as well as to one or more external connections. In many examples, the first voltage level is higher than the second voltage level. The external connections can be provided with conductive pads for coupling to solder balls between the integrated circuit device and a carrier circuit board. The carrier circuit board can have further electrical connections for one or more decoupling capacitors external to the integrated circuit device. Any of the structures, configurations, and arrangements described herein for decoupling capacitance might be employed in integrated circuit devices with internal voltage regulation elements. As such, all internally generated supplies of an integrated circuit device could be provided with improved capacitive decoupling to improve performance by at least providing a reduction in noise, transients, and other effects within voltage domains of the integrated circuit device.

Certain inventive aspects may be appreciated from the foregoing disclosure, of which the following are various examples.

Example 1: An assembly, comprising a package assembly coupled to a motherboard and comprising a carrier circuit board and an integrated circuit device coupled to a first side of the carrier circuit board, and decoupling capacitors for the integrated circuit device conductively coupled between the motherboard and a second side of the carrier circuit board opposite from at least a portion of a footprint of the integrated circuit device on the carrier circuit board.

Example 2: The assembly of Example 1, where terminals of one or more of the decoupling capacitors are configured to conductively couple at least a portion of input power for the integrated circuit device from the motherboard to the carrier circuit board.

Example 3: The assembly of Examples 1-2, comprising the package assembly comprising an interposer circuit board disposed between the carrier circuit board and the motherboard and comprising at least one aperture to accommodate the decoupling capacitors, where a thickness of the interposer circuit board separates the carrier circuit board from the motherboard to account for at least a thickness of the decoupling capacitors.

Example 4: The assembly of Examples 1-3, where the interposer circuit board is configured to conductively couple one or more communication signals between the motherboard and the carrier circuit board, and where terminals of one or more of the decoupling capacitors are configured to conductively couple at least a portion of input power for the integrated circuit device from the motherboard to the carrier circuit board.

Example 5: The assembly of Examples 1-4, comprising potting material disposed at least between the decoupling capacitors to hold the decoupling capacitors with respect to the carrier circuit board during soldering of the package assembly to the motherboard.

Example 6: The assembly of Examples 1-5, comprising the carrier circuit board comprising at least one cavity formed in the second side of the carrier circuit board and having a depth to accommodate at least a thickness of the decoupling capacitors between the carrier circuit board and the motherboard, where the decoupling capacitors are conductively coupled to the motherboard and to the second side of the carrier circuit board within the at least one cavity.

Example 7: The assembly of Examples 1-6, comprising potting material deposited into the at least one cavity to fill spaces between individual ones of the decoupling capacitors.

Example 8: The assembly of Examples 1-7, comprising the carrier circuit board comprising cavities formed in the second side of the carrier circuit board, each cavity configured to accommodate at least one of the decoupling capacitors and having a depth to accommodate at least a thickness of the at least one of the decoupling capacitors between the carrier circuit board and the motherboard, where the decoupling capacitors are conductively coupled to the motherboard and to the second side of the carrier circuit board within associated cavities.

Example 9: The assembly of Examples 1-8, comprising potting material deposited into the cavities to fill spaces between walls of the cavities and corresponding ones of the decoupling capacitors.

Example 10: The assembly of Examples 1-9, the motherboard comprising at least one cavity formed in a surface of the motherboard facing the package assembly and having a depth that accommodates at least a thickness of the decoupling capacitors, where the decoupling capacitors are conductively coupled to the motherboard within the at least one cavity and to the second side of the carrier circuit board.

Example 11: The assembly of Examples 1-10, comprising the motherboard comprising cavities formed in a surface of the motherboard facing the package assembly, each cavity configured to accommodate at least one of the decoupling capacitors and having a depth to account for at least a thicknesses of the at least one of the decoupling capacitors between the carrier circuit board and the motherboard, where the decoupling capacitors are conductively coupled to the motherboard within the cavities and to the second side of the carrier circuit board.

Example 12: An integrated circuit assembly, comprising a carrier circuit board coupled on a first side to an integrated circuit device, and having at least one cavity formed into a second side corresponding to at least a portion of a footprint of the integrated circuit device, and decoupling capacitors for the integrated circuit device deposited into the at least one cavity and configured to conductively couple between a motherboard and the at least one cavity.

Example 13: The integrated circuit assembly of Example 12, where terminals of one or more of the decoupling capacitors are configured to conductively couple at least a portion of input power for the integrated circuit device from the motherboard to the carrier circuit board.

Example 14: The integrated circuit assembly of Examples 12-13, where the at least one cavity comprises a depth to accommodate at least a thickness of the decoupling capacitors between the carrier circuit board and the motherboard when the motherboard is mated to the carrier circuit board.

Example 15: The integrated circuit assembly of Examples 12-14, comprising potting material deposited into the at least one cavity to fill spaces between individual ones of the decoupling capacitors.

Example 16: The integrated circuit assembly of Examples 12-15, where the at least one cavity comprises more than one cavity each configured to accommodate at least one of the decoupling capacitors, and comprising potting material deposited into the more than one cavity to fill spaces between walls of the more than one cavity and corresponding ones of the decoupling capacitors.

Example 17: An apparatus, comprising a carrier circuit board coupled on a first side to an integrated circuit device, decoupling capacitors for the integrated circuit device coupled to a second side of the carrier circuit board opposite from at least a portion of a footprint of the integrated circuit device, where at least a portion of the decoupling capacitors are configured to conductively couple between a motherboard and the carrier circuit board. The apparatus also comprises an interposer circuit board coupled to the second side of the carrier circuit board and configured to accommodate a thickness of the decoupling capacitors between the carrier circuit board and a motherboard when mated to the interposer circuit board.

Example 18: The apparatus of Example 17, where terminals of at least the portion of the decoupling capacitors are configured to conductively couple at least a portion of input power for the integrated circuit device from the motherboard to the carrier circuit board.

Example 19: The apparatus of Examples 17-18, comprising the interposer circuit board having at least one aperture configured to accommodate the decoupling capacitors, where a thickness of the interposer circuit board separates the carrier circuit board from the motherboard to account for at least the thickness of the decoupling capacitors.

Example 20: The apparatus of Examples 17-19, where the interposer circuit board is configured to conductively couple one or more communication signals between the motherboard and the carrier circuit board, and where terminals of at least the portion of the decoupling capacitors are configured to conductively couple at least a portion of input power for the integrated circuit device from the motherboard to the carrier circuit board.

The functional block diagrams, operational scenarios and sequences, and flow diagrams provided in the Figures are representative of exemplary systems, environments, and methodologies for performing novel aspects of the disclosure. The descriptions and figures included herein depict specific implementations to teach those skilled in the art how to make and use the best option. For the purpose of teaching inventive principles, some conventional aspects have been simplified or omitted. Those skilled in the art will appreciate variations from these implementations that fall within the scope of the invention. Those skilled in the art will also appreciate that the features described above can be combined in various ways to form multiple implementations. As a result, the invention is not limited to the specific implementations described above, but only by the claims and their equivalents.

What is claimed is:

1. An assembly, comprising:
a package assembly coupled to a motherboard and comprising a carrier circuit board and an integrated circuit device coupled to a first side of the carrier circuit board; and
decoupling capacitors for the integrated circuit device conductively coupled between the motherboard and a second side of the carrier circuit board opposite from at least a portion of a footprint of the integrated circuit device on the carrier circuit board.

2. The assembly of claim 1, wherein terminals of one or more of the decoupling capacitors are configured to conductively couple at least a portion of input power for the integrated circuit device from the motherboard to the carrier circuit board.

3. The assembly of claim 1, comprising:
the package assembly comprising an interposer circuit board disposed between the carrier circuit board and the motherboard and comprising at least one aperture to accommodate the decoupling capacitors, wherein a thickness of the interposer circuit board separates the carrier circuit board from the motherboard to account for at least a thickness of the decoupling capacitors.

4. The assembly of claim 3, wherein the interposer circuit board is configured to conductively couple one or more communication signals between the motherboard and the carrier circuit board, and wherein terminals of one or more of the decoupling capacitors are configured to conductively couple at least a portion of input power for the integrated circuit device from the motherboard to the carrier circuit board.

5. The assembly of claim 1, comprising:
potting material disposed at least between the decoupling capacitors to hold the decoupling capacitors with respect to the carrier circuit board during soldering of the package assembly to the motherboard.

6. The assembly of claim 1, comprising:
the carrier circuit board comprising at least one cavity formed in the second side of the carrier circuit board and having a depth to accommodate at least a thickness of the decoupling capacitors between the carrier circuit board and the motherboard, wherein the decoupling capacitors are conductively coupled to the motherboard and to the second side of the carrier circuit board within the at least one cavity.

7. The assembly of claim 6, comprising:
potting material deposited into the at least one cavity to fill spaces between individual ones of the decoupling capacitors.

8. The assembly of claim 1, comprising:
the carrier circuit board comprising cavities formed in the second side of the carrier circuit board, each cavity configured to accommodate at least one of the decoupling capacitors and having a depth to accommodate at least a thickness of the at least one of the decoupling capacitors between the carrier circuit board and the motherboard, wherein the decoupling capacitors are conductively coupled to the motherboard and to the second side of the carrier circuit board within associated cavities.

9. The assembly of claim 8, comprising:
potting material deposited into the cavities to fill spaces between walls of the cavities and corresponding ones of the decoupling capacitors.

10. The assembly of claim 1, comprising:
the motherboard comprising at least one cavity formed in a surface of the motherboard facing the package assembly and having a depth that accommodates at least a thickness of the decoupling capacitors, wherein the decoupling capacitors are conductively coupled to the motherboard within the at least one cavity and to the second side of the carrier circuit board.

11. The assembly of claim 1, comprising:
the motherboard comprising cavities formed in a surface of the motherboard facing the package assembly, each cavity configured to accommodate at least one of the decoupling capacitors and having a depth to account for at least a thicknesses of the at least one of the decoupling capacitors between the carrier circuit board and the motherboard, wherein the decoupling capacitors are conductively coupled to the motherboard within the cavities and to the second side of the carrier circuit board.

12. An integrated circuit assembly, comprising:
a carrier circuit board coupled on a first side to an integrated circuit device, and having at least one cavity formed into a second side corresponding to at least a portion of a footprint of the integrated circuit device; and
decoupling capacitors for the integrated circuit device deposited into the at least one cavity and configured to conductively couple between a motherboard and the at least one cavity.

13. The integrated circuit assembly of claim 12, wherein terminals of one or more of the decoupling capacitors are configured to conductively couple at least a portion of input power for the integrated circuit device from the motherboard to the carrier circuit board.

14. The integrated circuit assembly of claim 12, wherein the at least one cavity comprises a depth to accommodate at least a thickness of the decoupling capacitors between the carrier circuit board and the motherboard when the motherboard is mated to the carrier circuit board.

15. The integrated circuit assembly of claim 12, comprising:
potting material deposited into the at least one cavity to fill spaces between individual ones of the decoupling capacitors.

16. The integrated circuit assembly of claim 12, wherein the at least one cavity comprises more than one cavity each configured to accommodate at least one of the decoupling capacitors, and comprising:
potting material deposited into the more than one cavity to fill spaces between walls of the more than one cavity and corresponding ones of the decoupling capacitors.

17. An apparatus, comprising:
a carrier circuit board coupled on a first side to an integrated circuit device;
decoupling capacitors for the integrated circuit device coupled to a second side of the carrier circuit board opposite from at least a portion of a footprint of the integrated circuit device, wherein at least a portion of the decoupling capacitors are configured to conductively couple between a motherboard and the carrier circuit board; and
an interposer circuit board coupled to the second side of the carrier circuit board and configured to accommodate a thickness of the decoupling capacitors between the carrier circuit board and a motherboard when mated to the interposer circuit board.

18. The apparatus of claim 17, wherein terminals of at least the portion of the decoupling capacitors are configured to conductively couple at least a portion of input power for the integrated circuit device from the motherboard to the carrier circuit board.

19. The apparatus of claim 17, comprising:
the interposer circuit board having at least one aperture configured to accommodate the decoupling capacitors, wherein a thickness of the interposer circuit board separates the carrier circuit board from the motherboard to account for at least the thickness of the decoupling capacitors.

20. The apparatus of claim 17, wherein the interposer circuit board is configured to conductively couple one or more communication signals between the motherboard and the carrier circuit board, and wherein terminals of at least the portion of the decoupling capacitors are configured to conductively couple at least a portion of input power for the integrated circuit device from the motherboard to the carrier circuit board.
